(19) United States
(12) Patent Application Publication
(10) Pub. No.: US 2024/0329484 A1
(43) Pub. Date: Oct. 3, 2024

(54) TARGETED MESSAGING IN A FACILITY

(71) Applicant: View, Inc., Milpitas, CA (US)

(72) Inventors: Nitesh Trikha, Pleasanton, CA (US); Rao P. Mulpuri, Saratoga, CA (US); Rahul Bammi, Los Altos, CA (US); Tommy Cheung, Hillsborough, CA (US); Tanya Makker, Milpitas, CA (US)

(21) Appl. No.: 18/281,913

(22) PCT Filed: Mar. 17, 2022
(86) PCT No.: PCT/US2022/020730

§ 371 Date: Sep. 13, 2023

Related U.S. Application Data
(63) Continuation-in-part of application No. PCT/US2020/053641, filed on Sep. 30, 2020.
Application No. PCT/US2022/020730 is a continuation-in-part of application No. 16/950,774, filed on Nov. 17, 2020, now abandoned.
Application No. 16/950,774 is a continuation of application No. 16/608,157, filed on Oct. 24, 2019, now Pat. No. 11,886,089.
Application No. PCT/US2022/020730 is a continuation-in-part of application No. 17/081,809, filed on Oct. 27, 2020, now Pat. No. 11,460,749.
Application No. 17/081,809 is a continuation of application No. 16/608,159, filed on Oct. 24, 2019, now Pat. No. 11,300,849.
(60) Provisional application No. 63/163,305, filed on Mar. 19, 2021.
(60) Provisional application No. 62/911,271, filed on Oct. 5, 2019.
(60) Provisional application No. 62/952,207, filed on Dec. 20, 2019.
(60) Provisional application No. 62/975,706, filed on Feb. 12, 2020.
(60) Provisional application No. 63/085,254, filed on Sep. 30, 2020.
(60) Provisional application No. 62/607,618, filed on Dec. 19, 2017.
(60) Provisional application No. 62/523,606, filed on Jun. 22, 2017.
(60) Provisional application No. 62/507,704, filed on May 17, 2017.
(60) Provisional application No. 62/490,457, filed on Apr. 26, 2017.

(51) Int. Cl. G02F 1/163; B32B 17/10; E06B 9/24; G02F 1/15; G02F 1/155; G05B 15/02; G05B 19/042; G06F 3/041; G06F 3/044; G06F 3/14; G09F 19/22; G09G 3/34; G09G 3/38; H02J 50/20; H02J 50/80; H04K 3/00; H10K 50/80; H10K 59/65

(52) U.S. Cl. CPC G02F 1/163; B32B 17/10513; E06B 9/24; G02F 1/15; G02F 1/155; G05B 15/02; G05B 19/042; G05B 19/0426; G06F 3/0412; G06F 3/044; G06F 3/1446; G09F 19/227; G09G 3/38; H02J 50/20; H02J 50/80; H10K 50/80; H10K 59/65; B32B 2419/00; E06B 2009/2417; E06B 2009/2464; G05B 2219/25011; G05B 2219/25252; G05B 2219/2614; G05B 2219/2628; G05B 2219/2642; G09G 3/3433; G09G 2300/02; G09G 2300/023; G09G 2300/026; G09G 2300/04; G09G 2370/02; G09G 2370/06; G09G 2370/16; H04K 3/45

(57) ABSTRACT

A digital interface allows a content manager and/or content provider to couple to an interactive device (e.g., transparent media display coupled to a tintable window) in a facility, and engage with target personnel in a digital experience. The content may be personalized for the target personnel interacting with the interactive device, and may include a message such as an advertisement.

### RELATED APPLICATIONS

This application claims priority from U.S. Provisional Patent Application Ser. No. 63/163,305, filed Mar. 19, 2021, titled, “TARGETED MESSAGING IN A FACILITY,” which is incorporated by reference herein in its entirety. This application is related to International Patent Application Serial No. PCT/US20/53641, filed Sep. 30, 2020, titled, “Tandem Vision Window and Media Display,” which claims priority to U.S. Provisional Patent Application Ser. No. 62/911,271, filed Oct. 5, 2019, titled, “Tandem Vision Window and Transparent Display,” to U.S. Provisional Patent Application Ser. No. 62/952,207, filed Dec. 20, 2019, titled, “Tandem Vision Window and Transparent Display,” to U.S. Provisional Patent Application Ser. No. 62/975,706, filed Feb. 12, 2020, titled, “Tandem Vision Window and Media Display,” to U.S. Provisional Patent Application Ser. No. 63/085,254, filed Sep. 30, 2020, titled, “Tandem Vision Window and Media Display,” to International Patent Application Serial No. PCT/US21/23834, filed Mar. 24, 2021, titled, “Access and Messaging in a Multi Client Network,” which claims priority to U.S. Provisional Patent Application Ser. No. 63/000,342, filed Mar. 26, 2020, titled, “Messaging In A Client Network.” This application is also a Continuation-in-Part of U.S. patent application Ser. No. 16/950,774 filed Nov. 17, 2020, titled “DISPLAYS FOR TINTABLE WINDOWS,” that is a Continuation of U.S. patent application Ser. No. 16/608,157, filed Oct. 24, 2019, titled, “Displays For Tintable Windows,” that is a National Stage Entry filing of International Patent Application Serial No. PCT/US18/29476, filed Apr. 25, 2018, titled, “Displays For Tintable Windows,” that claims priority to (i) U.S. Provisional Patent Application Ser. No. 62/607,618, filed Dec. 19, 2017, titled, “Electrochromic Windows With Transparent Display Technology Field,” (ii) U.S. Provisional Patent Application Ser. No. 62/523,606, filed Jun. 22, 2017, titled, “Electrochromic Windows With Transparent Display Technology,” (iii) U.S. Provisional Patent Application Ser. No. 62/507,704, filed May 17, 2017, titled, “Electrochromic Windows With Transparent Display Technology,” (iv) U.S. Provisional Patent Application Ser. No. 62/506,514, filed May 15, 2017, titled, “Electrochromic Windows With Transparent Display Technology,” and (v) U.S. Provisional Patent Application Ser. No. 62/490,457, filed Apr. 26, 2017, titled, “Electrochromic Windows With Transparent Display Technology.” This application is also a Continuation-in-Part of U.S. patent application Ser. No. 17/081,809 filed Oct. 27, 2020, titled “TINTABLE WINDOW SYSTEM COMPUTING PLATFORM,” that is a Continuation of U.S. patent application Ser. No. 16/608,159 filed Oct. 24, 2019, titled “TINTABLE WINDOW SYSTEM COMPUTING PLATFORM,” that is a National Stage Entry of International Patent Application Serial No. PCT/US18/29406, filed Apr. 25, 2018, titled, “TINTABLE WINDOW SYSTEM COMPUTING PLATFORM,” that claims priority to (i) U.S. Provisional Patent Application Ser. No. 62/607,618, filed Dec. 19, 2017, titled, “ELECTROCHROMIC WINDOWS WITH TRANSPARENT DISPLAY TECHNOLOGY FIELD,” to (ii) U.S. Provisional Patent Application Ser. No. 62/523,606, filed Jun. 22, 2017, titled “ELECTROCHROMIC WINDOWS WITH TRANSPARENT DISPLAY TECHNOLOGY,” to (iii) U.S. Provisional Patent Application Ser. No. 62/507,704, filed May 17, 2017, titled, “ELECTROCHROMIC WINDOWS WITH TRANSPARENT DISPLAY TECHNOLOGY,” to (iv) U.S. Provisional Patent Application Ser. No. 62/506,514, filed May 15, 2017, titled, “ELECTROCHROMIC WINDOWS WITH TRANSPARENT DISPLAY TECHNOLOGY,” and to (v) U.S. Provisional Patent Application Ser. No. 62/490,457, filed Apr. 26, 2017, titled, “ELECTROCHROMIC WINDOWS WITH TRANSPARENT DISPLAY TECHNOLOGY.” This application is also a Continuation-in-Part of International Patent Application Serial No. PCT/US21/17946, filed Feb. 12, 2021 titled “Data and Power Network of a Facility,” which claims priority from U.S. Provisional Patent Application Ser. No. 63/146,365, filed Feb. 5, 2021, titled, “DATA AND POWER NETWORK OF A FACILITY,” from U.S. Provisional Patent Application Ser. No. 63/027,452, filed May 20, 2020, titled, “DATA AND POWER NETWORK OF AN ENCLOSURE,” from U.S. Provisional Patent Application Ser. No. 62/978,755, filed Feb. 19, 2020, titled, “DATA AND POWER NETWORK OF AN ENCLOSURE,” from U.S. Provisional Patent Application Ser. No. 62/977,001, filed Feb. 14, 2020, titled, “DATA AND POWER NETWORK OF AN ENCLOSURE.” This application is a Continuation-in-Part of International Patent Application Serial No. PCT/US20/32269, filed May 9, 2020, titled, “ANTENNA SYSTEMS FOR CONTROLLED COVERAGE IN BUILDINGS,” which claims priority to (i) U.S. Provisional Patent Application Ser. No. 62/850,993, filed May 21, 2019, titled, “ANTENNA SYSTEMS FOR CONTROLLED COVERAGE IN BUILDINGS,” and to (ii) U.S. Provisional Patent Application Ser. No. 62/845,764, filed May 9, 2019, titled, “ANTENNA SYSTEMS FOR CONTROLLED COVERAGE IN BUILDINGS.” This application is a Continuation in Part of U.S. patent application Ser. No. 15/709,339, filed Sep. 19, 2017, titled, “WINDOW ANTENNAS FOR EMITTING RADIO FREQUENCY SIGNALS.” This application is also a Continuation-in Part of U.S. patent application Ser. No. 16/099,424, filed Nov. 6, 2018, titled, “WINDOW ANTENNAS,” that is a National Stage Entry of International Patent Application Serial No. PCT/US17/31106, filed May 4, 2017, titled, “WINDOW ANTENNAS,” that claims benefit (i) from U.S. Provisional Patent Application Ser. No. 62/379,163, filed Aug. 24, 2016, “titled,” WINDOW ANTENNAS,” (ii) from U.S. Provisional Patent Application Ser. No. 62/352,508, filed Jun. 20, 2016, “titled,” WINDOW ANTENNAS,” (iii) from U.S. Provisional Patent Application Ser. No. 62/340,936, filed May 24, 2016, “titled,” WINDOW ANTENNAS,” and (iv) from U.S. Provisional Patent Application Ser. No. 62/333,103, filed May 6, 2016, “titled,” WINDOW ANTENNAS.” This application is a Continuation-in-Part of U.S. patent application Ser. No. 16/949,978, filed Nov. 23, 2020, titled, “WINDOW ANTENNAS,” which is a Continuation of U.S. patent application Ser. No. 16/849,540, filed Apr. 15, 2020, titled, “WINDOW ANTENNAS,” that is a Continuation of U.S. patent application Ser. No. 15/529,677, filed May 25, 2017, issued as U.S. patent Ser. No. 10,673,121 on Jun. 2, 2020, titled, “WINDOW ANTENNAS,” that is a National Stage Entry of International Patent Application Serial No. PCT/US15/62387, filed Nov. 24, 2015, titled, “WINDOW ANTENNAS,” which claims benefit from U.S. Provisional Patent Application Ser. No. 62/084,502, filed Nov. 25, 2014, titled, “WINDOW ANTENNAS.” This application is a Continuation-in-Part of U.S. patent application Ser. No. 16/946,140, filed Jun. 8, 2020, titled, “POWER DISTRIBUTION AND COMMUNICATIONS SYSTEMS FOR ELECTROCHROMIC DEVICES,” which is a Continuation of U.S. patent application Ser. No. 16/295,142, filed Mar. 7, 2019, and issued as U.S. patent Ser. No. 10,704,322 on Jul. 7, 2020, titled, “SIGNAL DISTRIBUTION NETWORKS FOR OPTICALLY SWITCHABLE WINDOWS,” which is a Continuation of U.S. patent application Ser. No. 15/268,204, filed Sep. 16, 2016, and issued as U.S. patent Ser. No. 10,253,558 on Apr. 9, 2019, titled, “POWER DISTRIBUTION NETWORKS FOR ELECTROCHROMIC DEVICES,” which claims benefit from U.S. Provisional Patent Application Ser. No. 62/220,514, filed Sep. 18, 2015, titled, “POWER DISTRIBUTION NETWORKS FOR ELECTROCHROMIC DEVICES.” This application is a Continuation-in-Part of U.S. patent application Ser. No. 16/949,800, filed Nov. 13, 2020, titled, “POWER DISTRIBUTION NETWORKS FOR ELECTROCHROMIC DEVICES,” which is a Continuation of U.S. patent application Ser. No. 16/439,376, filed Jun. 12, 2019, and issued as U.S. patent Ser. No. 10,859,887 on Dec. 8, 2020, titled, “POWER DISTRIBUTION NETWORKS FOR ELECTROCHROMIC DEVICES,” which is a Continuation of U.S. patent application Ser. No. 15/365,685, filed Nov. 30, 2016, and issued as U.S. patent Ser. No. 10,365,532 on Jul. 30, 2019, titled, “POWER DISTRIBUTION NETWORKS FOR ELECTROCHROMIC DEVICES,” which is a Continuation of U.S. patent application Ser. No. 15/268,204, filed Sep. 16, 2016, and issued as U.S. patent Ser. No. 10,253,558 on Apr. 9, 2019, titled, “POWER DISTRIBUTION NETWORKS FOR ELECTROCHROMIC DEVICES,” which claims benefit from U.S. Provisional Patent Application Ser. No. 62/220,514, filed Sep. 18, 2015, titled, “POWER DISTRIBUTION NETWORKS FOR ELECTROCHROMIC DEVICES.” This application is also a Continuation-in-Part of U.S. patent application Ser. No. 17/168,721, filed Feb. 5, 2021, titled, “POWER MANAGEMENT FOR ELECTROCHROMIC WINDOW NETWORKS,” which is a Continuation of U.S. patent application Ser. No. 16/380,929, filed Apr. 10, 2019, titled, “POWER MANAGEMENT FOR ELECTROCHROMIC WINDOW NETWORKS,” which (A) is a Continuation of U.S. patent application Ser. No. 16/297,461, filed Mar. 8, 2019, and issued as U.S. patent Ser. No. 10,908,471 on Feb. 2, 2021, titled, “POWER MANAGEMENT FOR ELECTROCHROMIC WINDOW NETWORKS,” which is a Continuation of U.S. patent application Ser. No. 15/910,931, filed on Mar. 2, 2018, titled, “POWER MANAGEMENT FOR ELECTROCHROMIC WINDOW NETWORKS,” which is a Continuation of U.S. patent application Ser. No. 15/739,562, filed Dec. 22, 2017, titled, “POWER MANAGEMENT FOR ELECTROCHROMIC WINDOW NETWORKS,” (B) that is a National Stage Entry of International Patent Application Serial No. PCT/US16/41176, filed Jul. 6, 2016, titled, “POWER MANAGEMENT FOR ELECTROCHROMIC WINDOW NETWORKS,” which claims benefit (i) from U.S. Provisional Patent Application Ser. No. 62/191,975, filed Jul. 13, 2015, titled, “POWER MANAGEMENT FOR ELECTROCHROMIC WINDOW NETWORKS,” and (ii) from U.S. Provisional Patent Application Ser. No. 62/190,012, filed Jul. 8, 2015, titled, “POWER MANAGEMENT FOR ELECTROCHROMIC WINDOW NETWORKS,” and (C) U.S. patent application Ser. No. 16/380,929, filed Apr. 10, 2019, titled, “POWER MANAGEMENT FOR ELECTROCHROMIC WINDOW NETWORKS,” is also a Continuation-in-Part of U.S. patent application Ser. No. 15/320,725, filed Dec. 20, 2016, issued as U.S. patent Ser. No. 10,481,459 on Nov. 19, 2019, titled, “CONTROL METHODS AND SYSTEMS FOR NETWORKS OF OPTICALLY SWITCHABLE WINDOWS DURING REDUCED POWER AVAILABILITY,” which is a National Stage Entry of International Patent Application Serial No. PCT/US15/38667, filed Jun. 30, 2015, titled, “CONTROL METHODS AND SYSTEMS FOR NETWORKS OF OPTICALLY SWITCHABLE WINDOWS DURING REDUCED POWER AVAILABILITY,” which claims benefit from U.S. Provisional Patent Application Ser. No. 62/019,325, filed Jun. 30, 2014, titled, “UNINTERRUPTABLE POWER SUPPLIES FOR NETWORKS OF OPTICALLY SWITCHABLE WINDOWS.” Each of the above is entirely incorporated herein by reference in its entirety.

### BACKGROUND

Buildings and other facilities can contain devices which interact with occupants of a facility to provide information, advertising, entertainment, education, alert, and other types of stimuli (e.g., sights, sounds, and/or environments). It may be advantageous to facilitate seamless interaction of a content manager and/or content provider with various interactive devices in network to disseminate appropriate stimuli, e.g., which network facilitates control of the various interactive devices. The one or more interactive devices may comprise sensors or emitters. The emitters may comprise a media display, lighting, odor dispensers, gas (e.g., air, carbon dioxide, or humidity) valve, speaker, heater, or cooler. For example, it may be challenging to provide contextualized information to targeted person(s) in a facility having interactive media display constructs (e.g., media displays integrated within windows comprising insulated glass units, tintable windows, or smart window component), which information is geared towards preferences of the target personnel and/or engagement with the target personnel. The media display may comprise s light emitting diode (LED) display such as an organic LED (OLED) display, e.g., a transparent OLED display (TOLED).

Various facilities (e.g., buildings) have windows installed, e.g., in their facades. The windows can provide a way to view an environment external to the facility. In some facilities, the window may take a substantial portion of a facility facade. By incorporating video display technology to windows, users may request utilization of the window surface area to view various media (e.g., for entertainment purposes, to process data, and/or to conduct a video conference). At times, a user may want to optimize usage of interior space to visualize the media (e.g., by using the window surface). The media may be electronic media and/or optical media. A user may request viewing the media with minimal impact on visibility through the window. The media may be displayed via a display that is at least partially transparent. At times viewing the media may require a tinted (e.g., darker) backdrop. At times, it may be desired for a content manager or content provider to determine the availability and capabilities of interactive devices as well as the contextual circumstances of personnel in the vicinity of the interactive devices in order to target useful, relevant information or other stimuli for dissemination to the personnel.

### SUMMARY

In an aspect hereof, various methods, apparatus, software, and programing language are configured to enable content manager operating systems (OS) and/or applications to gain access to various interactive facility devices as a digital experience (e.g., immersive digital experience). The interactive devices may comprise media displays, or device ensembles including sensor(s) and/or emitter(s), which are deployed in a facility. The interactive facility device will give the OS and/or application(s) of the content manager, information regarding itself. The provided information can be contextualized to the intended target person(s) (e.g., geared towards their preferences, whether the target persons are grouped or individualized), e.g., with an aim to engage the target person(s).

In an aspect, a digital interface is utilized that allows a content manager and/or (e.g., 3^{rd} party) content provider computer systems and/or applications to couple to an interactive device (e.g., window-mounted transparent display) in a facility, and engage with the device in a digital experience. For example, content is personalized for a building occupant (e.g., target personnel) interacting with the system, e.g., via a transparent display on a window or with any other interactive device(s) operatively coupled to the network. The content may include advertisement or other information (e.g., as disclosed herein) that is requested by the content manager, content provider and/or anticipated by the system for the target personnel, e.g., based on preferences or other data collected previously or contemporaneously by the system (e.g., comprising the network and the one or more interactive devices). The network may be operatively coupled to one or more sensors, transceivers, or control system.

In another aspect, a method of engaging at least one target personnel in a facility with a targeted stimulus, the method comprises: (A) providing device data to a device database that associates an interactive device with an interaction zone and with a stimulus type of the interactive device disposed in the facility, which interactive device is configured to provide the stimulus type to the interaction zone; (B) identifying a stimulus context pertinent to at least one target personnel that is presently at the interaction zone and/or that is projected to be in the interaction zone at a projected future time; (C) obtaining contextual data relating to the stimulus context, which contextual data is obtained from a contextual database; and (D) using the interactive device to disseminate the contextual data to the interaction zone using the interactive device, which dissemination of the contextual data is as the stimulus type.

In some embodiments, the stimulus type comprises an environmental stimulus. In some embodiments, the stimulus type comprises a stimulus type perceived by an average human. In some embodiments, the stimulus type comprises visual, auditory, olfactory, tactile, gustatory, electrical, or magnetic stimulus. In some embodiments, the stimulus type comprises temperature, gas content of the atmosphere at least in in the interaction zone of the facility, gas flow, gas pressure, electromagnetic radiation, sound, or gas content of the atmosphere. In some embodiments, the stimulus type affects or is effective at least the interaction zone of the facility. In some embodiments, at least in the interaction zone of the facility comprises at least in the facility. In some embodiments, the gas comprises air, oxygen, carbon dioxide, carbon monoxide, nitrous oxide, hydrogen sulfide, radon, or water vapor. In some embodiments, the gas flow comprises air flow. In some embodiments, the gas flow is from and/or to an opening of the facility. In some embodiments, the gas flow is from and/or to a vent of the facility. In some embodiments, the electromagnetic radiation comprises heat, visual media, or lighting. In some embodiments, the visual comprises projected media. In some embodiments, the stimulus type is interactive at least with the targeted personnel. In some embodiments, at least with the targeted personnel comprises personnel of the interaction zone. In some embodiments, at least with the targeted personnel comprises personnel of the facility. In some embodiments, the sound comprises audible message or music. In some embodiments, the sound and/or visual comprises entertainment warning, education, information, or direction. In some embodiments, the informative sound and/or visual type comprises news or advertisement. In some embodiments, providing the stimulus type to the interaction zone comprises providing the stimulus type that is accessible and/or perceived by one or more occupants of the interaction zone. In some embodiments, the one or more occupants comprise the target personnel. In some embodiments, the device data includes a designation of the interaction zone. In some embodiments, the designation comprises determining and/or using an isovist corresponding to the stimulus type of the interactive device. In some embodiments, the isovist is represented as a three-dimensional or as a two dimensional zone visible from a given point in the facility. In some embodiments, the given point is disposed in the interactive device. In some embodiments, designation of the interaction zone comprises an identifier of the interactive device, a geographic location of the interactive device, an orientation of the interactive device, or a boundary description of a zone in which the stimulus type is perceptible to the target personnel. In some embodiments, the contextual data is disseminated using the stimulus type from the interactive device, which stimulus type is recognizable by the at least one target personnel in the interaction zone. In some embodiments, (i) identification of the stimulus context, (ii) obtaining the contextual data, or (iii) identification of the stimulus context and obtaining of the contextual data, is provided by: a third party. In some embodiments, (i) identification of the stimulus context, (ii) obtaining the contextual data, or (iii) identification of the stimulus context and obtaining of the contextual data is provided by a media outlet. In some embodiments, (i) identification of the stimulus context, (ii) obtaining the contextual data, or (iii) identification of the stimulus context and obtaining of the contextual data is provided by a commercial outlet. In some embodiments, (i) identification of the stimulus context, (ii) obtaining the contextual data, or (iii) identification of the stimulus context and obtaining of the contextual data is provided by a security outlet. In some embodiments, (i) identification of the stimulus context, (ii) obtaining the contextual data, or (iii) identification of the stimulus context and obtaining of the contextual data is provided by a health outlet. In some embodiments, (i) identification of the stimulus context, (ii) obtaining the contextual data, or (iii) identification of the stimulus context and obtaining of the contextual data is provided by an owner, lessor, manager, and/or messenger of the facility. In some embodiments, the at least one target personnel comprises a target personnel presently at the interaction zone. In some embodiments, the at least one target personnel comprises a target personnel that is projected to be in the interaction zone at a projected future time. In some embodiments, the at least one target personnel comprises (i) a target personnel that is presently at the interaction zone, and (ii) a target personnel that is projected to be in the interaction zone at a projected future time. In some embodiments, a location of the target personnel at a projected future time is determined based at least in part on a path projection. In some embodiments, a location of the target personnel at a future time is determined based at least in part on an electronically stored schedule and/or calendar of one or more activities taking place in the facility. In some embodiments, a location of the target personnel at a future time is determined based at least in part on an electronically stored schedule and/or calendar of the target personnel. In some embodiments, a location of the target personnel is determined using geolocation data. In some embodiments, the geolocation data is obtained from an identification tag and/or a mobile device. In some embodiments, the interactive device disseminates the contextual data as projected media. In some embodiments, the interactive device comprises a media projector. In some embodiments, the projected media comprises a message. In some embodiments, the message comprises a commercial message, a health related message, a security related message, an informative message regarding the facility, or an informative message regarding activities in the facility. In some embodiments, the facility comprises an airport, a bank, a hospital, a sport arena, a hotel, a club, a restaurant, a country club, a resort, a mall, a shop, a theater, a transportation terminal, a school, a museum, an office, a gym, a warehouse, a distribution center, or a factory. In some embodiments, the interactive device disseminates the contextual data as projected light. In some embodiments, the interactive device comprises a lamp. In some embodiments, the projected light comprises an intermittent illumination. In some embodiments, the projected light is colored. In some embodiments, the projected light is patterned. In some embodiments, the interactive device comprises a laser, and wherein the laser projects imagery or a worded message. In some embodiments, the interactive device disseminates the contextual data as projected sound. In some embodiments, the interactive device comprises a loudspeaker. In some embodiments, the projected sound comprises an audible message. In some embodiments, the projected sound comprises a musical tune. In some embodiments, the projected sound comprises white noise. In some embodiments, the interactive device disseminates the contextual data as a projected temperature, and wherein the stimulus type is thermal. In some embodiments, the interactive device comprises a heating ventilation and air conditioning system (HVAC), a heater, a cooler, an air vent, or a tintable window. In some embodiments, the stimulus context of the projected temperature comprises an ambient temperature, an individual preference of the targeted personnel, or a health factor of the targeted personnel. In some embodiments, the ambient temperature is an external temperature to the facility. In some embodiments, the stimulus context of the projected temperature comprises an alerting of the targeted personnel by providing a cooling temperature aiming to increase an alertness of the targeted personnel. In some embodiments, the interactive device disseminates the contextual data as a projected gas. In some embodiments, the projected gas comprises air. In some embodiments, the interactive device comprises a heating ventilation and air conditioning system (HVAC), a heater, a cooler, an air vent, a door, a window, a media display, a security system, a gas source, a hygienic system, or a health system. In some embodiments, the interactive device comprises a sensor, an emitter, a transceiver, a controller, or a processor. In some embodiments, the stimulus context of the projected gas is determined at least in part by a sensor comprising a carbon dioxide (CO2) sensor, an oxygen sensor, a volatile organic compound (VOC) sensor, or a particulate matter sensor. In some embodiments, the method is carried out at least in part by a local network. In some embodiments, the local network comprises cables configured to transmit communication data and power on one cable. In some embodiments, the communication data comprises control data configured to control (i) one or more devices of the facility other than the interactive device and/or (ii) an environment of at least a portion of the facility other than the interaction zone. In some embodiments, the communication data comprises cellular communication conforming to at least third, fourth, or fifth generation cellular communication. In some embodiments, the communication data comprises phone communication. In some embodiments, the communication data comprises media streaming. In some embodiments, the media streaming comprises television, movie, stills, gaming, video conferencing, or data sheets. In some embodiments, the media streaming comprises media utilized by an industry sector or by a governmental sector. In some embodiments, the media streaming comprises media utilized in entertainment, health, construction, aviation, security, technology, biotechnology, legal, banking, monetary, automotive, agricultural, communication, education, food, computer, military, oil and gas, sports, manufacturing, or in waste management industry. In some embodiments, the stimulus type is a first stimulus type, wherein the method further comprises engaging the at least one target personnel in the interaction zone of the facility with at least one stimulus type different than the first stimulus type. In some embodiments, the method further comprises: (a) providing at least one other device data to at least one other device database that associates at least one other interactive device with the interaction zone and with at least one other stimulus type of the at least one other interactive device disposed in the facility, which at least one other interactive device is configured to provide the at least one other stimulus type to the interaction zone; (b) identifying at least one other stimulus context pertinent to at least one target personnel that is presently at the interaction zone and/or that is projected to be in the interaction zone at a projected future time; (c) obtaining at least one other contextual data relating to the at least one other stimulus context, which at least one other contextual data is obtained from at least one other contextual database; and (d) using the at least one other interactive device to disseminate the at least one other contextual data to the interaction zone using the at least one other interactive device, which dissemination of the at least one other contextual data is as the at least one other stimulus type. In some embodiments, at least one of (A), (B), (C) and (D) occurs before at least one of (a), (b), (c), and (d). In some embodiments, at least one of (A), (B), (C) and (D) occurs after at least one of (a), (b), (c), and (d). In some embodiments, at least one of (A), (B), (C) and (D) occurs contemporaneously with at least one of (a), (b), (c), and (d). In some embodiments, a non-transitory computer readable program instructions for engaging at least one target personnel in a facility with a targeted stimulus, the non-transitory computer readable program instructions, when read by one or more processors, causes the one or more processors to execute operations of any of the methods of any of the above embodiments.

In another aspect, a non-transitory computer readable program instructions for engaging at least one target personnel in a facility with a targeted stimulus, the non-transitory computer readable program instructions, when read by one or more processors, causes the one or more processors to execute operations comprises: (A) providing, or directing provision of, device data to a device database that associates an interactive device with an interaction zone and with a stimulus type of the interactive device disposed in the facility, which interactive device is configured to provide the stimulus type to the interaction zone; (B) identifying, or directing identification of, a stimulus context pertinent to at least one target personnel that is presently at the interaction zone and/or that is projected to be in the interaction zone at a projected future time; (C) obtaining, or directing obtaining, contextual data relating to the stimulus context, which contextual data is obtained from a contextual database; and (D) using, or directing usage of, the interactive device to disseminate the contextual data to the interaction zone using the interactive device, which dissemination of the contextual data is as the stimulus type, wherein the one or more processors are operatively coupled to the device database, to the interactive device, and to the contextual database.

In some embodiments, an apparatus for engaging at least one target personnel in a facility with a targeted stimulus, the apparatus comprising at least one controller configured to execute operations of any of the methods of any of the above embodiments. In some embodiments, the at least one controller comprises circuitry.

In another aspect, an apparatus for engaging at least one target personnel in a facility with a targeted stimulus, the apparatus comprises at least one controller configured to: (A) operatively couple to a device database, to an interactive device, and to a contextual database; (B) provide, or direct provision of, device data to the device database that associates the interactive device with an interaction zone and with a stimulus type of the interactive device disposed in the facility, which interactive device is configured to provide the stimulus type to the interaction zone; (C) identify, or direct identification of, a stimulus context pertinent to at least one target personnel that is presently at the interaction zone and/or that is projected to be in the interaction zone at a projected future time; (D) obtain, or direct obtaining, contextual data relating to the stimulus context, which contextual data is obtained from the contextual database; and (E) use, or direct usage of, the interactive device to disseminate the contextual data to the interaction zone using the interactive device, which dissemination of the contextual data is as the stimulus type.

In some embodiments, a system for engaging at least one target personnel in a facility with a targeted stimulus, the system comprising a network configured to facilitate execution of operations of any of the methods of any of the above embodiments, and associated apparatuses.

In another aspect, a system for engaging at least one target personnel in a facility with a targeted stimulus, the apparatus comprises: a device database; an interactive device; a contextual database; and a network operatively coupled to the device database, to the interactive device, and to the contextual database, which network is configured to facilitate: (B) providing device data to the device database that associates the interactive device with an interaction zone and with a stimulus type of the interactive device disposed in the facility, which interactive device is configured to provide the stimulus type to the interaction zone; (C) identifying a stimulus context pertinent to at least one target personnel that is presently at the interaction zone and/or that is projected to be in the interaction zone at a projected future time; (D) obtaining contextual data relating to the stimulus context, which contextual data is obtained from the contextual database; and (E) using the interactive device to disseminate the contextual data to the interaction zone using the interactive device, which dissemination of the contextual data is as the stimulus type.

In some embodiments, the network is configured to facilitate at least in part by being configured to transmit protocols relating to providing the device data, identifying the stimulus context, obtaining the contextual data, and using the interactive device.

In another aspect, a method for managing delivery of targeted stimulus from contextual data sources to one or more interactive devices in a facility, comprises: (A) deploying an interactive device in the facility, which interactive device is configured to provide a stimulus type to at least one target personnel; (B) mapping an interaction zone in the facility where the stimulus type is perceptible by the target personnel; (C) discovering device data that enables remote engagement with at least one interaction capability of the interactive device; (D) publishing the device data and a representation of the interaction zone in a database available to a content manager; (E) using the database and a stimulus context pertinent to the at least one target personnel that is presently at and/or that is projected to be in the interaction zone at a future time, to disseminate contextual data to the interaction zone using the interactive device, which contextual data is obtained from a contextual database.

In some embodiments, the stimulus type comprises an environmental stimulus. In some embodiments, the stimulus type comprises a stimulus type perceived by an average human. 1. In some embodiments, the stimulus type comprises visual, auditory, olfactory, tactile, gustatory, electrical, or magnetic stimulus. In some embodiments, the stimulus type comprises temperature, gas content of the atmosphere at least in in the interaction zone of the facility, gas flow, gas pressure, electromagnetic radiation, visuals, sound, or gas content of the atmosphere. In some embodiments, the stimulus type affects or is effective at least the interaction zone of the facility. In some embodiments, at least in the interaction zone of the facility comprises at least in the facility. In some embodiments, the gas comprises air, oxygen, carbon dioxide, carbon monoxide, nitrous oxide, hydrogen sulfide, radon, or water vapor. In some embodiments, the gas flow comprises air flow. In some embodiments, the gas flow is from and/or to an opening of the facility. In some embodiments, the gas flow is from and/or to a vent of the facility. In some embodiments, the electromagnetic radiation comprises heat, visual media, or lighting. In some embodiments, the visual media comprises projected media. In some embodiments, the stimulus type is interactive at least with the targeted personnel. In some embodiments, at least with the targeted personnel comprises personnel of the interaction zone. In some embodiments, at least with the targeted personnel comprises personnel of the facility. In some embodiments, the sound comprises audible message or music. In some embodiments, the sound and/or visual comprises entertainment warning, education, information, or direction. In some embodiments, the informative sound and/or visual type comprises news or advertisement. In some embodiments, providing the stimulus type to the interaction zone comprises providing the stimulus type that is accessible and/or perceived by one or more occupants of the interaction zone. In some embodiments, the one or more occupants comprise the target personnel. In some embodiments, the device data includes a designation of the interaction zone. In some embodiments, the designation comprises determining and/or using an isovist corresponding to the stimulus type of the interactive device. In some embodiments, the isovist is represented as a three-dimensional or as a two dimensional zone visible from a given point in the facility. In some embodiments, the given point is disposed in the interactive device. In some embodiments, designation of the interaction zone comprises an identifier of the interactive device, a geographic location of the interactive device, an orientation of the interactive device, or a boundary description of a zone in which the stimulus type is perceptible to the target personnel. In some embodiments, the contextual data is disseminated using the stimulus type from the interactive device, which stimulus type is recognizable by the at least one target personnel in the interaction zone. In some embodiments, (i) identification of the stimulus context, (ii) obtaining the contextual data, or (iii) identification of the stimulus context and obtaining of the contextual data, is provided by a third party. In some embodiments, (i) identification of the stimulus context, (ii) obtaining the contextual data, or (iii) identification of the stimulus context and obtaining of the contextual data is provided by a media outlet. In some embodiments, (i) identification of the stimulus context, (ii) obtaining the contextual data, or (iii) identification of the stimulus context and obtaining of the contextual data is provided by a commercial outlet. In some embodiments, (i) identification of the stimulus context, (ii) obtaining the contextual data, or (iii) identification of the stimulus context and obtaining of the contextual data is provided by a security outlet. In some embodiments, (i) identification of the stimulus context, (ii) obtaining the contextual data, or (iii) identification of the stimulus context and obtaining of the contextual data is provided by a health outlet. In some embodiments, (i) identification of the stimulus context, (ii) obtaining the contextual data, or (iii) identification of the stimulus context and obtaining of the contextual data is provided by an owner, lessor, manager, and/or messenger of the facility. In some embodiments, the at least one target personnel comprises a target personnel presently at the interaction zone. In some embodiments, the at least one target personnel comprises a target personnel that is projected to be in the interaction zone at a projected future time. In some embodiments, the at least one target personnel comprises (i) a target personnel that is presently at the interaction zone, and (ii) a target personnel that is projected to be in the interaction zone at a projected future time. In some embodiments, a location of the target personnel at a projected future time is determined based at least in part on a path projection. In some embodiments, a location of the target personnel at a future time is determined based at least in part on an electronically stored schedule and/or calendar of one or more activities taking place in the facility. In some embodiments, a location of the target personnel at a future time is determined based at least in part on an electronically stored schedule and/or calendar of the target personnel. In some embodiments, a location of the target personnel is determined using geolocation data. In some embodiments, the geolocation data is obtained from an identification tag and/or a mobile device. In some embodiments, the interactive device disseminates the contextual data as projected media. In some embodiments, the interactive device comprises a media projector. In some embodiments, the projected media comprises a message. In some embodiments, the message comprises a commercial message, a health related message, a security related message, an informative message regarding the facility, or an informative message regarding activities in the facility. In some embodiments, the facility comprises an airport, a bank, a hospital, a sport arena, a hotel, a club, a restaurant, a country club, a resort, a mall, a shop, a theater, a transportation terminal, a school, a museum, an office, a gym, a warehouse, a distribution center, or a factory. In some embodiments, the interactive device disseminates the contextual data as projected light. In some embodiments, the interactive device comprises a lamp. In some embodiments, the projected light comprises an intermittent illumination. In some embodiments, the projected light is colored. In some embodiments, the projected light is patterned. In some embodiments, the interactive device comprises a laser, and wherein the laser projects imagery or a worded message. In some embodiments, the interactive device disseminates the contextual data as projected sound. In some embodiments, the interactive device comprises a loudspeaker. In some embodiments, the projected sound comprises an audible message. In some embodiments, the projected sound comprises a musical tune. In some embodiments, the projected sound comprises white noise. In some embodiments, the interactive device disseminates the contextual data as a projected temperature, and wherein the stimulus type is thermal. In some embodiments, the interactive device comprises a heating ventilation and air conditioning system (HVAC), a heater, a cooler, an air vent, or a tintable window. In some embodiments, the stimulus context of the projected temperature comprises an ambient temperature, an individual preference of the targeted personnel, or a health factor of the targeted personnel. In some embodiments, the ambient temperature is an external temperature to the facility. In some embodiments, the stimulus context of the projected temperature comprises an alerting of the targeted personnel by providing a cooling temperature aiming to increase an alertness of the targeted personnel. In some embodiments, the interactive device disseminates the contextual data as a projected gas. In some embodiments, the projected gas comprises air. In some embodiments, the interactive device comprises a heating ventilation and air conditioning system (HVAC), a heater, a cooler, an air vent, a door, a window, a media display, a security system, a gas source, a hygienic system, or a health system. In some embodiments, the interactive device comprises a sensor, an emitter, a transceiver, a controller, or a processor. In some embodiments, the stimulus context of the projected gas is determined at least in part by a sensor comprising a carbon dioxide (CO2) sensor, an oxygen sensor, a volatile organic compound (VOC) sensor, or a particulate matter sensor. In some embodiments, the method is carried out at least in part by a local network. In some embodiments, the local network comprises cables configured to transmit communication data and power on one cable. In some embodiments, the communication data comprises control data configured to control (i) one or more devices of the facility other than the interactive device and/or (ii) an environment of at least a portion of the facility other than the interaction zone. In some embodiments, the communication data comprises cellular communication conforming to at least third, fourth, or fifth generation cellular communication. In some embodiments, the communication data comprises phone communication. In some embodiments, the communication data comprises media streaming. In some embodiments, the media streaming comprises television, movie, stills, gaming, video conferencing, or data sheets. In some embodiments, the media streaming comprises media utilized by an industry sector or by a governmental sector. In some embodiments, the media streaming comprises media utilized in entertainment, health, construction, aviation, security, technology, biotechnology, legal, banking, monetary, automotive, agricultural, communication, education, food, computer, military, oil and gas, sports, manufacturing, or in waste management industry. In some embodiments, the stimulus type is a first stimulus type, wherein the method further comprises engaging the at least one target personnel in the interaction zone of the facility with at least one stimulus type different than the first stimulus type. In another aspect, a method, further comprises: (a) providing at least one other device data to at least one other device database that associates at least one other interactive device with the interaction zone and with at least one other stimulus type of the at least one other interactive device disposed in the facility, which at least one other interactive device is configured to provide the at least one other stimulus type to the interaction zone; (b) identifying at least one other stimulus context pertinent to at least one target personnel that is presently at the interaction zone and/or that is projected to be in the interaction zone at a projected future time; (c) obtaining at least one other contextual data relating to the at least one other stimulus context, which at least one other contextual data is obtained from at least one other contextual database; and (d) using the at least one other interactive device to disseminate the at least one other contextual data to the interaction zone using the at least one other interactive device, which dissemination of the at least one other contextual data is as the at least one other stimulus type.

In another aspect, a method for distributing data for enabling use of one or more interactive devices in a facility, comprises: (A) using an interactive device of the facility that is adapted to provide a stimulus type to at least one target personnel; (B) establishing one or more objects relating to interactive device data comprising a representation of an interaction zone in the facility where the stimulus type is perceptible by the at least one target personnel; (C) in a markup programming language, associating identifiers with the one or more objects; and (D) a user discovering the interactive device data at least in part by retrieving the identifiers to initiate a relationship with the interactive device to present contextual data at least in part by disseminating the stimulus type to the interaction zone using the interactive device.

In some embodiments, the interactive device data for the facility comprises (i) network addressing, (ii) physical location, (iii) purpose of the interactive device at a location, (iv) technical detail, (v) communication configuration, (vi) power configuration, or (vii) interactive device format in which the interactive device can interact with the at least one target personnel.

In some embodiments, the interactive device of the facility is adapted to provide a plurality of stimulus types to at least one target personnel. In some embodiments, the plurality of stimulus types comprises sound and visual stimulus types. In some embodiments, the stimulus type comprises a stimulus type perceived by an average human. In some embodiments, the stimulus type comprises visual, auditory, olfactory, tactile, gustatory, electrical, or magnetic stimulus. In some embodiments, the stimulus type comprises temperature, gas content of the atmosphere at least in in the interaction zone of the facility, gas flow, gas pressure, electromagnetic radiation, visuals, sound, or gas content of the atmosphere. In some embodiments, the stimulus type affects or is effective at least the interaction zone of the facility. In some embodiments, at least in the interaction zone of the facility comprises at least in the facility. In some embodiments, the gas comprises air, oxygen, carbon dioxide, carbon monoxide, nitrous oxide, hydrogen sulfide, radon, or water vapor. In some embodiments, the gas flow comprises air flow. In some embodiments, the gas flow is from and/or to an opening of the facility. In some embodiments, the gas flow is from and/or to a vent of the facility. In some embodiments, the electromagnetic radiation comprises heat, visual media, or lighting. In some embodiments, the visual media comprises projected media. In some embodiments, the stimulus type is interactive at least with the targeted personnel. In some embodiments, at least with the targeted personnel comprises personnel of the interaction zone. In some embodiments, at least with the targeted personnel comprises personnel of the facility. In some embodiments, the sound comprises audible message or music. In some embodiments, the sound and/or visual comprises entertainment warning, education, information, or direction. In some embodiments, the informative sound and/or visual type comprises news or advertisement. In some embodiments, providing the stimulus type to the interaction zone comprises providing the stimulus type that is accessible and/or perceived by one or more occupants of the interaction zone. In some embodiments, the one or more occupants comprise the target personnel. In some embodiments, the device data includes a designation of the interaction zone. In some embodiments, the designation comprises determining and/or using an isovist corresponding to the stimulus type of the interactive device. In some embodiments, the isovist is represented as a three-dimensional or as a two-dimensional zone visible from a given point in the facility. In some embodiments, the given point is disposed in the interactive device. In some embodiments, designation of the interaction zone comprises an identifier of the interactive device, a geographic location of the interactive device, an orientation of the interactive device, or a boundary description of a zone in which the stimulus type is perceptible to the target personnel. In some embodiments, the contextual data is disseminated using the stimulus type from the interactive device, which stimulus type is recognizable by the at least one target personnel in the interaction zone. In some embodiments, (i) identification of the stimulus context, (ii) obtaining the contextual data, or (iii) identification of the stimulus context and obtaining of the contextual data, is provided by a third party. In some embodiments, (i) identification of the stimulus context, (ii) obtaining the contextual data, or (iii) identification of the stimulus context and obtaining of the contextual data is provided by a media outlet. In some embodiments, (i) identification of the stimulus context, (ii) obtaining the contextual data, or (iii) identification of the stimulus context and obtaining of the contextual data is provided by a commercial outlet. In some embodiments, (i) identification of the stimulus context, (ii) obtaining the contextual data, or (iii) identification of the stimulus context and obtaining of the contextual data is provided by a security outlet. In some embodiments, (i) identification of the stimulus context, (ii) obtaining the contextual data, or (iii) identification of the stimulus context and obtaining of the contextual data is provided by a health outlet. In some embodiments, (i) identification of the stimulus context, (ii) obtaining the contextual data, or (iii) identification of the stimulus context and obtaining of the contextual data is provided by an owner, lessor, manager, and/or messenger of the facility. In some embodiments, the at least one target personnel comprises a target personnel presently at the interaction zone. In some embodiments, the at least one target personnel comprises a target personnel that is projected to be in the interaction zone at a projected future time. In some embodiments, the at least one target personnel comprises (i) a target personnel that is presently at the interaction zone, and (ii) a target personnel that is projected to be in the interaction zone at a projected future time. In some embodiments, a location of the target personnel at a projected future time is determined based at least in part on a path projection. In some embodiments, a location of the target personnel at a future time is determined based at least in part on an electronically stored schedule and/or calendar of one or more activities taking place in the facility. In some embodiments, a location of the target personnel at a future time is determined based at least in part on an electronically stored schedule and/or calendar of the target personnel. In some embodiments, a location of the target personnel is determined using geolocation data. In some embodiments, the geolocation data is obtained from an identification tag and/or a mobile device. In some embodiments, the interactive device disseminates the contextual data as projected media. In some embodiments, the interactive device comprises a media projector. In some embodiments, the projected media comprises a message. In some embodiments, the message comprises a commercial message, a health-related message, a security related message, an informative message regarding the facility, or an informative message regarding activities in the facility. In some embodiments, the facility comprises an airport, a bank, a hospital, a sport arena, a hotel, a club, a restaurant, a country club, a resort, a mall, a shop, a theater, a transportation terminal, a school, a museum, an office, a gym, a warehouse, a distribution center, or a factory. In some embodiments, the interactive device disseminates the contextual data as projected light. In some embodiments, the interactive device comprises a lamp. In some embodiments, the projected light comprises an intermittent illumination. In some embodiments, the projected light is colored. In some embodiments, the projected light is patterned. In some embodiments, the interactive device comprises a laser, and wherein the laser projects imagery or a worded message. In some embodiments, the interactive device disseminates the contextual data as projected sound. In some embodiments, the interactive device comprises a loudspeaker. In some embodiments, the projected sound comprises an audible message. In some embodiments, the projected sound comprises a musical tune. In some embodiments, the projected sound comprises white noise. In some embodiments, the interactive device disseminates the contextual data as a projected temperature, and wherein the stimulus type is thermal. In some embodiments, the interactive device comprises a heating ventilation and air conditioning system (HVAC), a heater, a cooler, an air vent, or a tintable window. In some embodiments, the stimulus context of the projected temperature comprises an ambient temperature, an individual preference of the targeted personnel, or a health factor of the targeted personnel. In some embodiments, the ambient temperature is an external temperature to the facility. In some embodiments, the stimulus context of the projected temperature comprises an alerting of the targeted personnel by providing a cooling temperature aiming to increase an alertness of the targeted personnel. In some embodiments, the interactive device disseminates the contextual data as a projected gas. In some embodiments, the projected gas comprises air. In some embodiments, the interactive device comprises a heating ventilation and air conditioning system (HVAC), a heater, a cooler, an air vent, a door, a window, a media display, a security system, a gas source, a hygienic system, or a health system. In some embodiments, the interactive device comprises a sensor, an emitter, a transceiver, a controller, or a processor. In some embodiments, the stimulus context of the projected gas is determined at least in part by a sensor comprising a carbon dioxide (CO2) sensor, an oxygen sensor, a volatile organic compound (VOC) sensor, or a particulate matter sensor. In some embodiments, the method is carried out at least in part by a local network. In some embodiments, the local network comprises cables configured to transmit communication data and power on one cable. In some embodiments, the communication data comprises control data configured to control (i) one or more devices of the facility other than the interactive device and/or (ii) an environment of at least a portion of the facility other than the interaction zone. In some embodiments, the communication data comprises cellular communication conforming to at least third, fourth, or fifth generation cellular communication. In some embodiments, the communication data comprises phone communication. In some embodiments, the communication data comprises media streaming. In some embodiments, the media streaming comprises television, movie, stills, gaming, video conferencing, or data sheets. In some embodiments, the media streaming comprises media utilized by an industry sector or by a governmental sector. In some embodiments, the media streaming comprises media utilized in entertainment, health, construction, aviation, security, technology, biotechnology, legal, banking, monetary, automotive, agricultural, communication, education, food, computer, military, oil and gas, sports, manufacturing, or in waste management industry. In some embodiments, the stimulus type is a first stimulus type, wherein the method further comprises engaging the at least one target personnel in the interaction zone of the facility with at least one stimulus type different than the first stimulus type. In another aspect, a method further comprises: (a) providing at least one other device data to at least one other device database that associates at least one other interactive device with the interaction zone and with at least one other stimulus type of the at least one other interactive device disposed in the facility, which at least one other interactive device is configured to provide the at least one other stimulus type to the interaction zone; (b) identifying at least one other stimulus context pertinent to at least one target personnel that is presently at the interaction zone and/or that is projected to be in the interaction zone at a projected future time; (c) obtaining at least one other contextual data relating to the at least one other stimulus context, which at least one other contextual data is obtained from at least one other contextual database; and (d) using the at least one other interactive device to disseminate the at least one other contextual data to the interaction zone using the at least one other interactive device, which dissemination of the at least one other contextual data is as the at least one other stimulus type. In some embodiments, a non-transitory computer readable program instructions for managing delivery of targeted stimulus from contextual data sources to one or more interactive devices in a facility, the non-transitory computer readable program instructions, when read by one or more processors, causes the one or more processors to execute operations of any of the methods of any of the above embodiments.

In another aspect, a non-transitory computer readable program instructions for managing delivery of targeted stimulus from contextual data sources to one or more interactive devices in a facility, the non-transitory computer readable program instructions, when read by one or more processors, causes the one or more processors to execute operations comprises: (A) deploying, or directing deployment of, an interactive device in the facility, which interactive device is configured to provide a stimulus type to at least one target personnel; (B) mapping, or directing mapping of, an interaction zone in the facility where the stimulus type is perceptible by the target personnel; (C) discovering, or directing discovery of, device data that enables remote engagement with at least one interaction capability of the interactive device; (D) publishing, or directing publication of, the device data and a representation of the interaction zone in a database available to a content manager; (E) using, or directing usage of, the database and a stimulus context pertinent to the at least one target personnel that is presently at and/or that is projected to be in the interaction zone at a future time, to disseminate contextual data to the interaction zone using the interactive device, which contextual data is obtained from a contextual database.

In some embodiments, an apparatus for managing delivery of targeted stimulus from contextual data sources to one or more interactive devices in a facility, the apparatus comprising at least one controller configured to execute operations of any of the methods of any of the above embodiments. In some embodiments, the at least one controller comprises circuitry.

In another aspect, an apparatus for managing delivery of targeted stimulus from contextual data sources to one or more interactive devices in a facility, the apparatus comprises at least one controller configured to: (A) operatively couple to an interactive device; (B) deploy, or direct deployment of, an interactive device in the facility, which interactive device is configured to provide a stimulus type to at least one target personnel; (C) map, or direct mapping of, an interaction zone in the facility where the stimulus type is perceptible by the target personnel; (D) discover, or direct discovery of, device data that enables remote engagement with at least one interaction capability of the interactive device; (E) publish, or direct publication of, the device data and a representation of the interaction zone in a database available to a content manager; and (F) use, or direct usage of, the database and a stimulus context pertinent to the at least one target personnel that is presently at and/or that is projected to be in the interaction zone at a future time, to disseminate contextual data to the interaction zone using the interactive device, which contextual data is obtained from a contextual database.

In some embodiments, a system for managing delivery of targeted stimulus from contextual data sources to one or more interactive devices in a facility, the system comprising a network configured to facilitate execution of operations of any of the methods of any of the above embodiments, and associated apparatuses.

In another aspect, a system for managing delivery of targeted stimulus from contextual data sources to one or more interactive devices in a facility, the apparatus comprises: an interactive device; and a network operatively coupled to the interactive device, which network is configured to facilitate: (A) deploying an interactive device in the facility, which interactive device is configured to provide a stimulus type to at least one target personnel; (B) mapping an interaction zone in the facility where the stimulus type is perceptible by the target personnel; (D) discovering device data that enables remote engagement with at least one interaction capability of the interactive device; (E) publishing the device data and a representation of the interaction zone in a database available to a content manager; and (F) using the database and a stimulus context pertinent to the at least one target personnel that is presently at and/or that is projected to be in the interaction zone at a future time, to disseminate contextual data to the interaction zone using the interactive device, which contextual data is obtained from a contextual database.

In some embodiments, the network is configured to facilitate at least in part by being configured to deploying the interactive device, mapping the interaction zone, discovering the device data, publishing the device data and the representation of the interaction zone, and using the database and the stimulus context.

In another aspect, the present disclosure provides systems, apparatuses (e.g., controllers), and/or non-transitory computer-readable medium (e.g., software) that implement any of the methods disclosed herein.

In another aspect, the present disclosure provides methods that use any of the systems, computer readable media, and/or apparatuses disclosed herein, e.g., for their intended purpose.

In another aspect, an apparatus comprises at least one controller that is programmed to direct a mechanism used to implement (e.g., effectuate) any of the method disclosed herein, which at least one controller is configured to operatively couple to the mechanism. In some embodiments, at least two operations (e.g., of the method) are directed/executed by the same controller. In some embodiments, at less at two operations are directed/executed by different controllers.

In another aspect, an apparatus comprises at least one controller that is configured (e.g., programmed) to implement (e.g., effectuate) any of the methods disclosed herein. The at least one controller may implement any of the methods disclosed herein. In some embodiments, at least two operations (e.g., of the method) are directed/executed by the same controller. In some embodiments, at less at two operations are directed/executed by different controllers.

In some embodiments, one controller of the at least one controller is configured to perform two or more operations. In some embodiments, two different controllers of the at least one controller are configured to each perform a different operation.

In another aspect, a system comprises at least one controller that is programmed to direct operation of at least one another apparatus (or component thereof), and the apparatus (or component thereof), wherein the at least one controller is operatively coupled to the apparatus (or to the component thereof). The apparatus (or component thereof) may include any apparatus (or component thereof) disclosed herein. The at least one controller may be configured to direct any apparatus (or component thereof) disclosed herein. The at least one controller may be configured to operatively couple to any apparatus (or component thereof) disclosed herein. In some embodiments, at least two operations (e.g., of the apparatus) are directed by the same controller. In some embodiments, at less at two operations are directed by different controllers.

In another aspect, a computer software product, comprising a non-transitory computer-readable medium in which program instructions are stored, which instructions, when read by at least one processor (e.g., computer), cause the at least one processor to direct a mechanism disclosed herein to implement (e.g., effectuate) any of the method disclosed herein, wherein the at least one processor is configured to operatively couple to the mechanism. The mechanism can comprise any apparatus (or any component thereof) disclosed herein. In some embodiments, at least two operations (e.g., of the apparatus) are directed/executed by the same processor. In some embodiments, at less at two operations are directed/executed by different processors.

In another aspect, the present disclosure provides a non-transitory computer-readable medium comprising machine-executable code that, upon execution by one or more processors, implements any of the methods disclosed herein. In some embodiments, at least two operations (e.g., of the method) are directed/executed by the same processor. In some embodiments, at less at two operations are directed/executed by different processors.

In another aspect, the present disclosure provides a non-transitory computer-readable medium comprising machine-executable code that, upon execution by one or more processors, effectuates directions of the controller(s) (e.g., as disclosed herein). In some embodiments, at least two operations (e.g., of the controller) are directed/executed by the same processor. In some embodiments, at less at two operations are directed/executed by different processors.

In another aspect, the present disclosure provides a computer system comprising one or more computer processors and a non-transitory computer-readable medium coupled thereto. The non-transitory computer-readable medium comprises machine-executable code that, upon execution by the one or more processors, implements any of the methods disclosed herein and/or effectuates directions of the controller(s) disclosed herein.

In another aspect, the present disclosure provides a non-transitory computer readable program instructions, the non-transitory computer readable program instructions, when read by one or more processors, causes the one or more processors to execute any operation of the methods disclosed herein, any operation performed (or configured to be performed) by the apparatuses disclosed herein, and/or any operation directed (or configured to be directed) by the apparatuses disclosed herein.

In some embodiments, the program instructions are inscribed in a non-transitory computer readable medium. In some embodiments, the program instructions are inscribed in non-transitory computer readable media. In some embodiments, at least two of the operations are executed by one of the one or more processors. In some embodiments, at least two of the operations are each executed by different processors of the one or more processors.

The content of this summary section is provided as a simplified introduction to the disclosure and is not intended to be used to limit the scope of any invention disclosed herein or the scope of the appended claims.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

These and other features and embodiments will be described in more detail with reference to the drawings.

### INCORPORATION BY REFERENCE

All publications, patents, and patent applications mentioned in this specification are herein incorporated by reference to the same extent as if each individual publication, patent, or patent application was specifically and individually indicated to be incorporated by reference.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings or figures (also “FIG.” and “FIGS.” herein), of which:

FIG. 1 schematically shows a control system architecture and a perspective view of a facility;

FIG. 2 shows a block diagram of a network coupled to devices;

FIG. 3 shows a communication network coupled to devices in various enclosures or floors;

FIG. 4 shows an arrangement of sensors and controller(s);

FIG. 5 shows an apparatus, its components, and connectivity options;

FIG. 6 schematically shows a building, a building network, and devices disposed in the building;

FIG. 7 schematically shows an isovist in a building;

FIG. 8 shows a flowchart depicting operations relating to an interactive device;

FIG. 9 schematically shows a system for engaging target personnel in a facility with targeted stimuli;

FIG. 10 schematically shows device data associated with an interactive device;

FIG. 11 shows a flowchart depicting operations taken by a content provider to disseminate requested media content;

FIG. 12 shows a flowchart depicting operations taken by a content provider to disseminate requested media content in an airport;

FIG. 13 shows a device database and a contextual database for disseminating desired media content in an airport;

FIG. 14 shows a flowchart depicting operations taken to disseminate personal information to employees or other occupants upon arrival to a facility;

FIG. 15 shows a device database and a contextual database for disseminating personal information to employees or other occupants upon arrival to a facility;

FIG. 16 schematically shows an example of a processing system;

FIG. 17 schematically shows an example of an electrochromic device; and

FIG. 18 schematically shows an example cross-section of an Integrated Glass Unit (IGU).

The figures and components therein may not be drawn to scale. Various components of the figures described herein may not be drawn to scale.

### DETAILED DESCRIPTION

While various embodiments of the invention have been shown, and described herein, it will be obvious to those skilled in the art that such embodiments are provided by way of example only. Numerous variations, changes, and substitutions may occur to those skilled in the art without departing from the invention. It should be understood that various alternatives to the embodiments of the invention described herein might be employed.

Terms such as “a,” “an,” and “the” are not intended to refer to only a singular entity but include the general class of which a specific example may be used for illustration. The terminology herein is used to describe specific embodiments of the invention(s), but their usage does not delimit the invention(s).

When ranges are mentioned, the ranges are meant to be inclusive, unless otherwise specified. For example, a range between value 1 and value 2 is meant to be inclusive and include value 1 and value 2. The inclusive range will span any value from about value 1 to about value 2. The term “adjacent” or “adjacent to,” as used herein, includes “next to,” “adjoining,” “in contact with,” and “in proximity to.”

As used herein, including in the claims, the conjunction “and/or” in a phrase such as “including X, Y, and/or Z”, refers to in inclusion of any combination or plurality of X, Y, and Z. For example, such phrase is meant to include X. For example, such phrase is meant to include Y. For example, such phrase is meant to include Z. For example, such phrase is meant to include X and Y. For example, such phrase is meant to include X and Z. For example, such phrase is meant to include Y and Z. For example, such phrase is meant to include a plurality of Xs. For example, such phrase is meant to include a plurality of Ys. For example, such phrase is meant to include a plurality of Zs. For example, such phrase is meant to include a plurality of Xs and a plurality of Ys. For example, such phrase is meant to include a plurality of Xs and a plurality of Zs. For example, such phrase is meant to include a plurality of Ys and a plurality of Zs. For example, such phrase is meant to include a plurality of Xs and Y. For example, such phrase is meant to include a plurality of Xs and Z. For example, such phrase is meant to include a plurality of Ys and Z. For example, such phrase is meant to include X and a plurality of Ys. For example, such phrase is meant to include X and a plurality of Zs. For example, such phrase is meant to include Y and a plurality of Zs. The conjunction “and/or” is meant to have the same effect as the phrase “X, Y, Z, or any combination or plurality thereof.” The conjunction “and/or” is meant to have the same effect as the phrase “one or more X, Y, Z, or any combination thereof.”

The term “operatively coupled” or “operatively connected” refers to a first element (e.g., mechanism) that is coupled (e.g., connected) to a second element, to allow the intended operation of the second and/or first element. The coupling may comprise physical or non-physical coupling (e.g., communicative coupling). The non-physical coupling may comprise signal-induced coupling (e.g., wireless coupling). Coupled can include physical coupling (e.g., physically connected), or non-physical coupling (e.g., via wireless communication). Operatively coupled may comprise communicatively coupled.

An element (e.g., mechanism) that is “configured to” perform a function includes a structural feature that causes the element to perform this function. A structural feature may include an electrical feature, such as a circuitry or a circuit element. A structural feature may include an actuator. A structural feature may include a circuitry (e.g., comprising electrical or optical circuitry). Electrical circuitry may comprise one or more wires. Optical circuitry may comprise at least one optical element (e.g., beam splitter, mirror, lens and/or optical fiber). A structural feature may include a mechanical feature. A mechanical feature may comprise a latch, a spring, a closure, a hinge, a chassis, a support, a fastener, or a cantilever, and so forth. Performing the function may comprise utilizing a logical feature. A logical feature may include programming instructions. Programming instructions may be executable by at least one processor. Programming instructions may be stored or encoded on a medium accessible by one or more processors. Additionally, in the following description, the phrases “operable to,” “adapted to,” “configured to,” “designed to,” “programmed to,” or “capable of” may be used interchangeably where appropriate.

In some embodiments, an enclosure comprises an area defined by at least one structure. The at least one structure may comprise at least one wall. An enclosure may comprise and/or enclose one or more sub-enclosure. The at least one wall may comprise metal (e.g., steel), clay, stone, plastic, glass, plaster (e.g., gypsum), polymer (e.g., polyurethane, styrene, or vinyl), asbestos, fiber-glass, concrete (e.g., reinforced concrete), wood, paper, or a ceramic. The at least one wall may comprise wire, bricks, blocks (e.g., cinder blocks), tile, drywall, or frame (e.g., steel frame).

In some embodiments, the enclosure comprises one or more openings. The one or more openings may be reversibly closable. The one or more openings may be permanently open. A fundamental length scale of the one or more openings may be smaller relative to the fundamental length scale of the wall(s) that define the enclosure. A fundamental length scale may comprise a diameter of a bounding circle, a length, a width, or a height. A surface of the one or more openings may be smaller relative to the surface the wall(s) that define the enclosure. The opening surface may be a percentage of the total surface of the wall(s). For example, the opening surface can measure at most about 30%, 20%, 10%, 5%, or 1% of the walls(s). The wall(s) may comprise a floor, a ceiling, or a side wall. The closable opening may be closed by at least one window or door. The enclosure may be at least a portion of a facility. The facility may comprise a building. The enclosure may comprise at least a portion of a building. The building may be a private building and/or a commercial building. The building may comprise one or more floors. The building (e.g., floor thereof) may include at least one of: a room, hall, foyer, attic, basement, balcony (e.g., inner, or outer balcony), stairwell, corridor, elevator shaft, façade, mezzanine, penthouse, garage, porch (e.g., enclosed porch), terrace (e.g., enclosed terrace), cafeteria, and/or Duct. In some embodiments, an enclosure may be stationary (e.g., a building) or movable (e.g., a train, an airplane, a ship, a vehicle, or a rocket).

In some embodiments, the enclosure encloses an atmosphere. The atmosphere may comprise one or more gases. The gases may include inert gases (e.g., comprising argon or nitrogen) and/or non-inert gases (e.g., comprising oxygen or carbon dioxide). The gasses may include harmful gasses such as radon, hydrogen sulfide, Nitric oxide (NO) and/or nitrogen dioxide (NO₂)). The enclosure atmosphere may resemble an atmosphere external to the enclosure (e.g., ambient atmosphere) in at least one external atmosphere characteristic that includes: temperature, relative gas content, gas type (e.g., humidity, and/or oxygen level), debris (e.g., dust and/or pollen), and/or gas velocity. The enclosure atmosphere may be different from the atmosphere external to the enclosure in at least one external atmosphere characteristic that includes: temperature, relative gas content, gas type (e.g., humidity, and/or oxygen level), debris (e.g., dust and/or pollen), and/or gas velocity. For example, the enclosure atmosphere may be less humid (e.g., drier) than the external (e.g., ambient) atmosphere. For example, the enclosure atmosphere may contain the same (e.g., or a substantially similar) oxygen-to-nitrogen ratio as the atmosphere external to the enclosure. The velocity of the gas in the enclosure may be (e.g., substantially) similar throughout the enclosure. The velocity of the gas in the enclosure may be different in different portions of the enclosure (e.g., by flowing gas through to a vent that is coupled with the enclosure).

Certain disclosed embodiments provide a network infrastructure in the enclosure (e.g., a facility such as a building). The network infrastructure is available for various purposes such as for providing communication and/or power services. The communication services may comprise high bandwidth (e.g., wireless and/or wired) communications services. The communication services can be to occupants of a facility and/or users outside the facility (e.g., building). The network infrastructure may work in concert with, or as a partial replacement of, the infrastructure of one or more cellular carriers. The network infrastructure can be provided in a facility that includes electrically switchable windows. Examples of components of the network infrastructure include a high speed backhaul. The network infrastructure may include at least one cable, switch, physical antenna, transceivers, sensor, transmitter, receiver, radio, processor and/or controller (that may comprise a processor). The network infrastructure may be operatively coupled to, and/or include, a wireless network. The network infrastructure may comprise wiring. One or more sensors can be deployed (e.g., installed) in an environment as part of installing the network and/or after installing the network. The network may be a local network. The network may comprise a cable configured to transmit power and communication in a single cable. The communication can be one or more types of communication. The communication can comprise cellular communication abiding by at least a second generation (2G), third generation (3G), fourth generation (4G) or fifth generation (5G) cellular communication protocol. The communication may comprise media communication facilitating stills, music, or moving picture streams (e.g., movies or videos). The communication may comprise data communication (e.g., sensor data). The communication may comprise control communication, e.g., to control the one or more nodes operatively coupled to the networks. The network may comprise a first (e.g., cabling) network installed in the facility. The network may comprise a (e.g., cabling) network installed in an envelope of the facility (e.g., such as in an envelope of an enclosure of the facility. For example, in an envelope of a building included in the facility).

In some embodiments, an enclosure includes one or more sensors. The sensor may facilitate controlling the environment of the enclosure such that inhabitants of the enclosure may have an environment that is more comfortable, delightful, beautiful, healthy, productive (e.g., in terms of inhabitant performance), easer to live (e.g., work) in, or any combination thereof. The sensor(s) may be configured as low or high resolution sensors. Sensor may provide on/off indications of the occurrence and/or presence of a particular environmental event (e.g., one pixel sensors). In some embodiments, the accuracy and/or resolution of a sensor may be improved via artificial intelligence analysis of its measurements. Examples of artificial intelligence techniques that may be used include: reactive, limited memory, theory of mind, and/or self-aware techniques know to those skilled in the art). Sensors may be configured to process, measure, analyze, detect and/or react to one or more of: data, temperature, humidity, sound, force, pressure, electromagnetic waves, position, distance, movement, flow, acceleration, speed, vibration, dust, light, glare, color, gas(es), and/or other aspects (e.g., characteristics) of an environment (e.g., of an enclosure). The gases may include volatile organic compounds (VOCs). The gases may include carbon monoxide, carbon dioxide, water vapor (e.g., humidity), oxygen, radon, and/or hydrogen sulfide. The gasses may include any gas disclosed herein.

In some embodiments, a plurality of devices may be operatively (e.g., communicatively) coupled to the control system. The plurality of devices may be disposed in a facility (e.g., including a building and/or room). The control system may comprise the hierarchy of controllers. The devices may comprise an emitter, a sensor, or a window (e.g., IGU). The device may be any device as disclosed herein. At least two of the plurality of devices may be of the same type. For example, two or more IGUs may be coupled to the control system. At least two of the plurality of devices may be of different types. For example, a sensor and an emitter may be coupled to the control system. At times the plurality of devices may comprise at least 20, 50, 100, 500, 1000, 2500, 5000, 7500, 10000, 50000, 100000, or 500000 devices. The plurality of devices may be of any number between the aforementioned numbers (e.g., from 20 devices to 500000 devices, from 20 devices to 50 devices, from 50 devices to 500 devices, from 500 devices to 2500 devices, from 1000 devices to 5000 devices, from 5000 devices to 10000 devices, from 10000 devices to 100000 devices, or from 100000 devices to 500000 devices). For example, the number of windows in a floor may be at least 5, 10, 15, 20, 25, 30, 40, or 50. The number of windows in a floor can be any number between the aforementioned numbers (e.g., from 5 to 50, from 5 to 25, or from 25 to 50). At times, the devices may be in a multi-story building. At least a portion of the floors of the multi-story building may have devices controlled by the control system (e.g., at least a portion of the floors of the multi-story building may be controlled by the control system). For example, the multi-story building may have at least 2, 8, 10, 25, 50, 80, 100, 120, 140, or 160 floors that are controlled by the control system. The number of floors (e.g., devices therein) controlled by the control system may be any number between the aforementioned numbers (e.g., from 2 to 50, from 25 to 100, or from 80 to 160). The floor may be of an area of at least about 150 m², 250 m², 500 m², 1000 m², 1500 m², or 2000 square meters (m²). The floor may have an area between any of the aforementioned floor area values (e.g., from about 150 m² to about 2000 m², from about 150 m² to about 500 m², from about 250 m² to about 1000 m², or from about 1000 m² to about 2000 m²). The facility may comprise a commercial or a residential building. The commercial building may include tenant(s) and/or owner(s). The residential facility may comprise a multi or a single family building. The residential facility may comprise an apartment complex. The residential facility may comprise a single family home. The residential facility may comprise multifamily homes (e.g., apartments). The residential facility may comprise townhouses. The facility may comprise residential and commercial portions.

In some embodiments, the sensor(s) are operatively coupled to at least one controller and/or processor. Sensor readings may be obtained by one or more processors and/or controllers. A controller may comprise a processing unit (e.g., CPU or GPU). A controller may receive an input (e.g., from at least one sensor). The controller may include circuitry, electrical wiring, optical wiring, socket, and/or outlet. A controller may deliver an output. A controller may comprise multiple (e.g., sub-) controllers. The controller may be a part of a control system. A control system may comprise a master controller, floor (e.g., comprising network controller) controller, or a local controller. The local controller may be a window controller (e.g., controlling an optically switchable window), enclosure controller, or component controller. The controller can be a device controller (e.g., any device disclosed herein). For example, a controller may be a part of a hierarchal control system (e.g., comprising a main controller that directs one or more controllers, e.g., floor controllers, local controllers (e.g., window controllers), enclosure controllers, and/or component controllers). A physical location of the controller type in the hierarchal control system may be changing. For example, at a first time: a first processor may assume a role of a main controller, a second processor may assume a role of a floor controller, and a third processor may assume the role of a local controller. At a second time: the second processor may assume a role of a main controller, the first processor may assume a role of a floor controller, and the third processor may remain with the role of a local controller. At a third time: the third processor may assume a role of a main controller, the second processor may assume a role of a floor controller, and the first processor may assume the role of a local controller. A controller may control one or more devices (e.g., be directly coupled to the devices). A controller (e.g., a local controller) may be disposed proximal to the one or more devices it is controlling. For example, a controller may control an optically switchable device (e.g., IGU), an antenna, a sensor, and/or an output device (e.g., a light source, sounds source, smell source, gas source, HVAC outlet, or heater). In one embodiment, a floor controller may direct one or more window controllers, one or more enclosure controllers, one or more component controllers, or any combination thereof. The floor controller may comprise a floor controller. For example, the floor (e.g., comprising network) controller may control a plurality of local (e.g., comprising window) controllers. A plurality of local controllers may be disposed in a portion of a facility (e.g., in a portion of a building). The portion of the facility may be a floor of a facility. For example, a floor controller may be assigned to a floor. In some embodiments, a floor may comprise a plurality of floor controllers, e.g., depending on the floor size and/or the number of local controllers coupled to the floor controller. For example, a floor controller may be assigned to a portion of a floor. For example, a floor controller may be assigned to a portion of the local controllers disposed in the facility. For example, a floor controller may be assigned to a portion of the floors of a facility. A master controller may be coupled to one or more floor controllers. The floor controller may be disposed in the facility. The master controller may be disposed in the facility, or external to the facility. The master controller may be disposed in the cloud. A controller may be a part of, or be operatively coupled to, a building management system. A controller may receive one or more inputs. A controller may generate one or more outputs. The controller may be a single input single output controller (SISO) or a multiple input multiple output controller (MIMO). A controller may interpret an input signal received. A controller may acquire data from the one or more components (e.g., sensors). Acquire may comprise receive or extract. The data may comprise measurement, estimation, determination, generation, or any combination thereof. A controller may comprise feedback control. A controller may comprise feed-forward control. Control may comprise on-off control, proportional control, proportional-integral (PI) control, or proportional-integral-derivative (PID) control. Control may comprise open loop control, or closed loop control. A controller may comprise closed loop control. A controller may comprise open loop control. A controller may comprise a user interface. A user interface may comprise (or operatively coupled to) a keyboard, keypad, mouse, touch screen, microphone, speech recognition package, camera, imaging system, or any combination thereof. Outputs may include a display (e.g., screen), speaker, or printer.

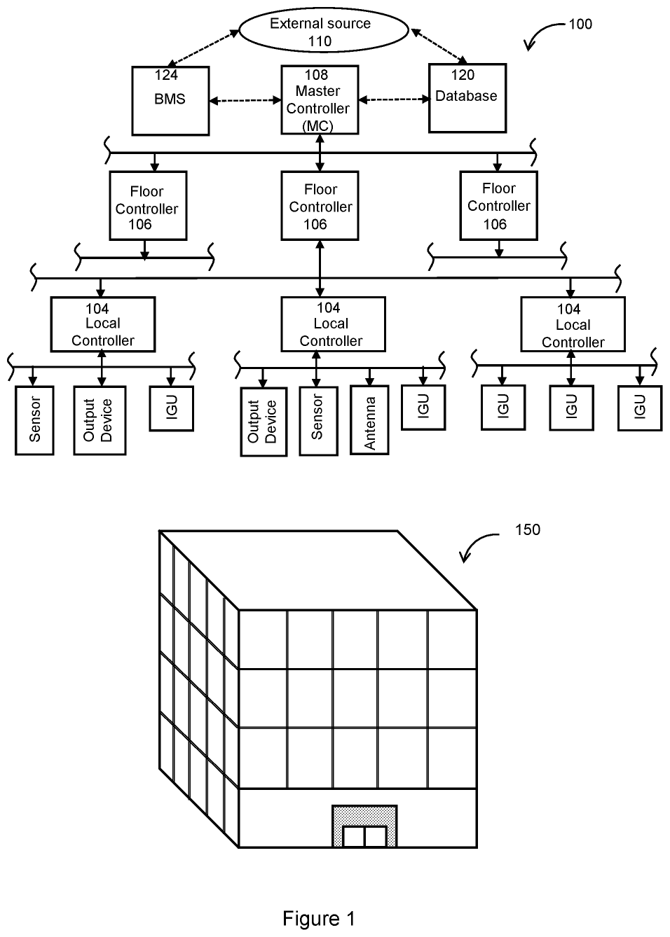

FIG. 1 shows an example of a control system architecture 100 comprising a master controller 108 that controls floor controllers 106, that in turn control local controllers 104. In some embodiments, a local controller controls one or more IGUs, one or more sensors, one or more output devices (e.g., one or more emitters), or any combination thereof. FIG. 1 shows an example of a configuration in which the master controller is operatively coupled (e.g., wirelessly and/or wired) to a building management system (BMS) 124 and to a database 120. Arrows in FIG. 1 represents communication pathways. A controller may be operatively coupled (e.g., directly/indirectly and/or wired and/wirelessly) to an external source 110. The external source may comprise a network. The external source may comprise one or more sensor or output device. The external source may comprise a cloud-based application and/or database. The communication may be wired and/or wireless. The external source may be disposed external to the facility. For example, the external source may comprise one or more sensors and/or antennas disposed, e.g., on a wall or on a ceiling of the facility. The communication may be monodirectional or bidirectional. In the example shown in FIG. 1, the communication all communication arrows are meant to be bidirectional.

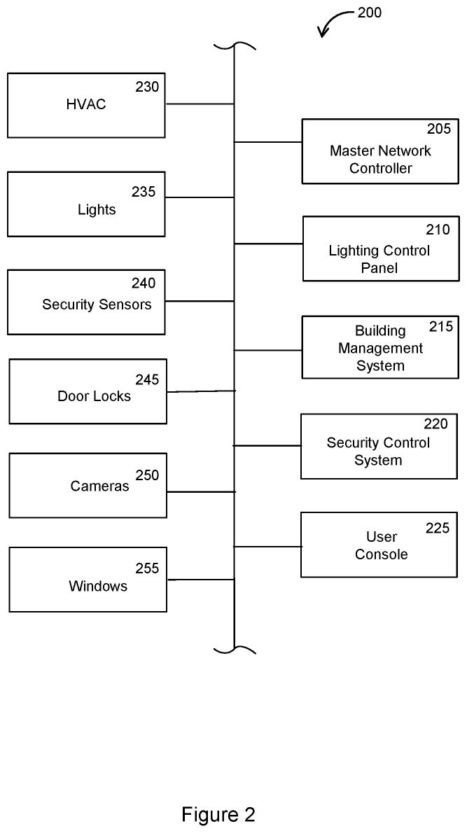

FIG. 2 depicts a block diagram of one example of a building network 200 for a building. Building network 200 may employ any number of different communication protocols (e.g., including Building Automation and Control networks (BACnet)). As shown, building network 200 includes a master network controller 205, a lighting control panel 210, a building management system 215, a security control system 220, and a user console 225. These different controllers and systems in the building may be used to receive input from and/or control an HVAC system 230, lights 235, security sensors 240, door locks 245, cameras 250, and tintable windows 255 of the building.

In some embodiments, master network controller 205 functions in a similar manner as master controller 108 described with respect to FIG. 1. Lighting control panel 210 (FIG. 2) may include circuitry to control any device disclosed herein (e.g., the interior lighting that is operatively coupled to the controller). The device may comprise interior lighting, exterior lighting, emergency warning lights, emergency exit signs, or emergency floor egress lighting. The lighting may be associated with the building. The lighting may be operatively coupled to the controller. Lighting control panel 210 may include other device(s) (e.g., an occupancy sensor). Building management system (BMS) 215 may include a computer server that receives data from, and/or issues commands to the other system(s) and/or controller(s) operatively coupled to the network 200. For example, BMS 215 may receive data from and/or may issue commands to the master network controller 205, lighting control panel 210, and/or security control system 220. Security control system 220 may include magnetic card access, turnstiles, solenoid driven door locks, surveillance cameras, burglar alarms, and/or metal detectors. User console 225 may include a computer terminal that can be used by the building manager to schedule operations of, control, monitor, optimize, and/or troubleshoot the different systems of the facility (e.g., building). Software such as those from Tridium, Inc., may generate visual representations of data from different systems for user console 225. The one or more different controls may (e.g., each) control device(s). Master network controller 205 may control windows 255. Lighting control panel 210 may control lights 235. BMS 215 may (e.g., directly or indirectly) control HVAC 230. Security control system 220 may control security sensors 240, door locks 245, and cameras 250. Data may be exchanged and/or shared between (e.g., all of) the different devices and controllers that are part of the building network 200. The master controller 205 may control (e.g., directly or indirectly) various lower hierarchy controllers such as floor controllers and/or local controllers. For example, a master controller may control a tintable window by controlling a floor controller that controls a local controller controlling the tintable window.

In some cases, at least a portion of the systems of BMS (e.g., 215) and/or building network (e.g., 200) may run according to daily, monthly, quarterly, and/or yearly schedules. For example, the lighting control system, the window control system, the HVAC, and/or the security system may operate on a 24-hour schedule accounting for when people are in the facility (e.g., building) during the workday. At least two device categories (e.g., of 230, 235, 240, 245, 250, and 255) may run at a different schedule from each other. At least two device categories (e.g., of 230, 235, 240, 245, 250, and 255) may run at (e.g., substantially) the same schedule. For example, at night the building may enter an energy savings mode, and during the day the systems may operate in a manner that minimizes the energy consumption of the building while providing for occupant comfort, safety, and health. As another example, the systems may shut down or enter an energy savings mode over a holiday period.

The scheduling information may be combined with geographical information. Geographical information may include the latitude and/or longitude of the building. Geographical information may include information about the direction that at least one façade (e.g., side) of the building faces. Using such information, different rooms on different sides of the building may be controlled in different manners. For example, for East facing rooms of the building in the winter, the window controller may instruct the windows to have no tint in the morning so that the room warms up due to sunlight shining in the room and the lighting control panel may instruct the lights to be dim because of the lighting from the sunlight. The west facing windows may be controllable by the occupants of the room in the morning because the tint of the windows on the west side may have no impact on energy savings. The modes of operation of the East facing windows and the West facing windows may switch in the evening (e.g., when the sun is setting, the west facing windows may not be tinted to allow sunlight in for both heat and lighting).

In some embodiments, a plurality of assemblies (e.g., device ensembles) are deployed as interconnected (e.g., having IP) addressable nodes (e.g., devices) within a processing system throughout a particular enclosure (e.g., a building), portions thereof (e.g., rooms or floors), or spanning a plurality of such enclosures (e.g., as part of a facility).

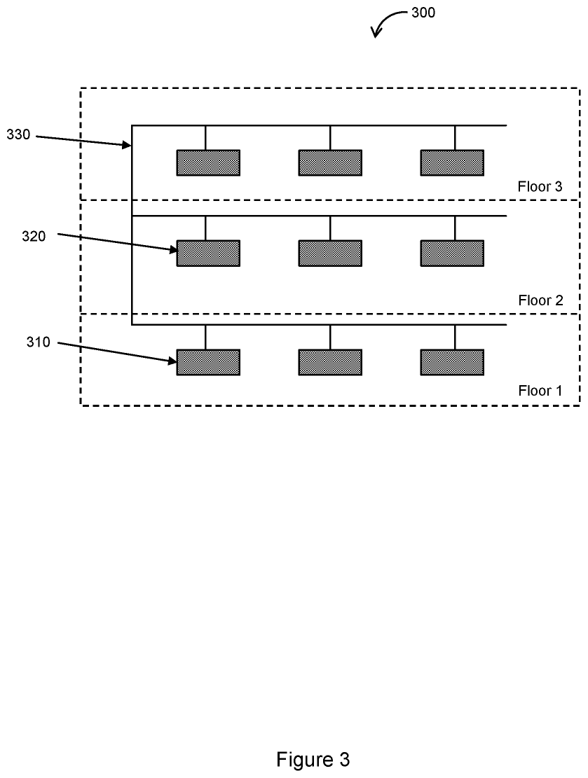

FIG. 3 shows a schematic example of a network system within an enclosure (e.g., building) having a plurality of sub-enclosures (e.g., floors). In the example of FIG. 3, the enclosure 300 is a building having floor 1, floor 2, and floor 3. The enclosure 300 includes a network 330 (e.g., a wired network) that is provided to communicatively couple any addressable circuitry (e.g., addressable node) such as a device or a device ensemble represented by 310 and 320. In the example shown in FIG. 3, the three floors are sub enclosures within the enclosure 300. At least two devices can be of a different type from each other. At least two devices can be of the same type. At least two device ensembles can be of a different type from each other. At least two device ensembles can be of the same type.

In some embodiments, an enclosure includes one or more sensors and/or emitters. The sensor and/or emitter may facilitate controlling the environment of the enclosure, e.g., such that inhabitants of the enclosure may have an environment that is more comfortable, delightful, beautiful, healthy, productive (e.g., in terms of inhabitant performance), easer to live (e.g., work) in, or any combination thereof. The sensor(s) may be configured as low or high resolution sensors. The sensor may provide on/off indications of the occurrence and/or presence of an environmental event (e.g., one pixel sensors). In some embodiments, the accuracy and/or resolution of a sensor may be improved via artificial intelligence (abbreviated herein as “AI”) analysis of its measurements. Examples of artificial intelligence techniques that may be used include: reactive, limited memory, theory of mind, and/or self-aware techniques know to those skilled in the art). Sensors (including their circuitry) may be configured to process, measure, analyze, detect and/or react to: data, temperature, humidity, sound, force, pressure, concentration, electromagnetic waves, position, distance, movement, flow, acceleration, speed, vibration, dust, light, glare, color, gas(es) type, and/or any other aspects (e.g., characteristics) of an environment (e.g., of an enclosure). The gases may include volatile organic compounds (VOCs). The gases may include carbon monoxide, carbon dioxide, water vapor (e.g., humidity), oxygen, radon, and/or hydrogen sulfide. The one or more sensors may be calibrated in a factory setting and/or in the facility. A sensor may be optimized to performing accurate measurements of one or more environmental characteristics present in the factory setting and/or in the facility in which it is deployed.

In some embodiments, a plurality of sensors of the same type are distributed in a plurality of locations or in a housing. For example, at least one of the plurality of sensors of the same type, may be part of an ensemble. For example, at least two of the plurality of sensors of the same type, may be part of at least two different ensembles. The device ensembles may be distributed in the facility (e.g., in an enclosure thereof). An enclosure may comprise a conference room or a cafeteria. For example, a plurality of sensors of the same type may measure an environmental characteristic (e.g., parameter) in the conference room. Responsive to measurement of the environmental parameter of an enclosure, a parameter topology of the enclosure may be generated. A parameter topology may be generated utilizing output signals from any type of sensor or device ensemble, e.g., as disclosed herein. Parameter topologies may be generated for any enclosure of a facility such as conference rooms, hallways, bathrooms, cafeterias, garages, auditoriums, utility rooms, storage facilities, equipment rooms, piers (e.g., electricity and/or elevator pier), and/or elevators. Examples of artificial intelligence techniques that may be used include: reactive, limited memory, theory of mind, and/or self-aware techniques know to those skilled in the art). Sensors and their associated circuitry may be configured to process, measure, analyze, detect and/or react to one or more of: data, temperature, humidity, sound, force, pressure, electromagnetic waves, position, distance, movement, flow, acceleration, speed, vibration, dust, light, glare, color, gas(es), pathogen exposure (or likely pathogen exposure), and/or other aspects (e.g., characteristics) of an environment (e.g., of an enclosure). The gases may include volatile organic compounds (VOCs). The gases may include carbon monoxide, carbon dioxide, formaldehyde, Napthalene, Taurine, water vapor (e.g., humidity), oxygen, radon, and/or hydrogen sulfide. The one or more sensors may be calibrated in a factory setting. A sensor may be optimized to be capable of performing accurate measurements of one or more environmental characteristics present in the factory setting. In some instances, a factory calibrated sensor may be less optimized for operation in a target environment. For example, a factory setting may comprise a different environment than a target environment. The target environment can be an environment in which the sensor is deployed. The target environment can be an environment in which the sensor is expected and/or destined to operate. The target environment may differ from a factory environment. A factory environment corresponds to a location at which the sensor was assembled and/or built. The target environment may comprise a factory in which the sensor was not assembled and/or built. In some instances, the factory setting may differ from the target environment to the extent that sensor readings captured in the target environment are erroneous (e.g., to a measurable extent). In this context, “erroneous” may refer to sensor readings that deviate from a specified accuracy (e.g., specified by a manufacture of the sensor). In some situations, a factory-calibrated sensor may provide readings that do not meet accuracy specifications (e.g., by a manufacturer) when operated in the target environments.

In some embodiments, processing sensor data comprises performing sensor data analysis. The sensor data analysis may comprise at least one rational decision making process, and/or learning (e.g., using logic). The sensor data analysis may be utilized to adjust an environment, e.g., by adjusting one or more components that affect the environment of the enclosure. The data analysis may be performed by a machine based system (e.g., a circuitry). The circuitry may be of a processor. The sensor data analysis may utilize artificial intelligence. The sensor data analysis may rely on one or more models (e.g., mathematical models). In some embodiments, the sensor data analysis comprises linear regression, least squares fit, Gaussian process regression, kernel regression, nonparametric multiplicative regression (NPMR), regression trees, local regression, semiparametric regression, isotonic regression, multivariate adaptive regression splines (MARS), logistic regression, robust regression, polynomial regression, stepwise regression, ridge regression, lasso regression, elasticnet regression, principal component analysis (PCA), singular value decomposition, fuzzy measure theory, Borel measure, Han measure, risk-neutral measure, Lebesgue measure, group method of data handling (GMDH), Naive Bayes classifiers, k-nearest neighbors algorithm (k-NN), support vector machines (SVMs), neural networks, support vector machines, classification and regression trees (CART), random forest, gradient boosting, or generalized linear model (GLM) technique.

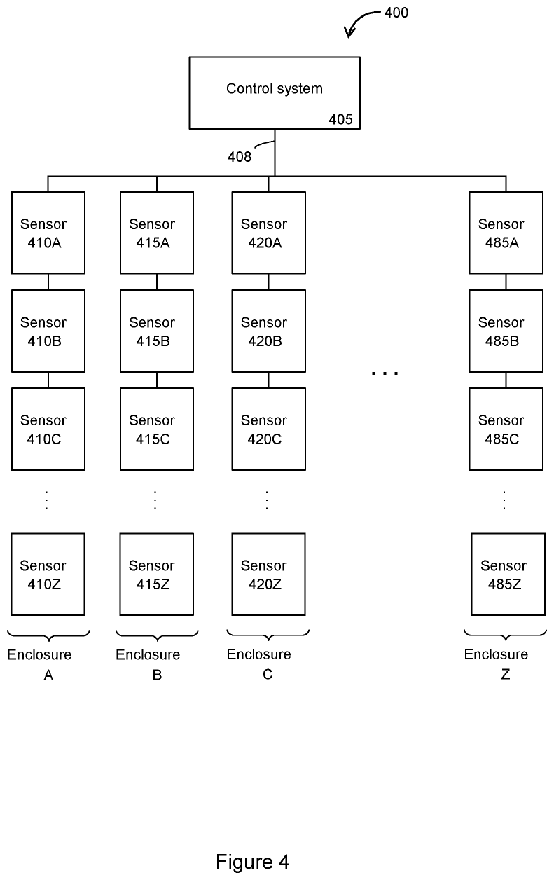

FIG. 4 shows an example of a diagram 400 of an arrangement of sensors distributed among enclosures. In the example shown in FIG. 4, a control system 405 is communicatively coupled (e.g., linked) 408 with sensors located in enclosure A (sensors 410A, 410B, 410C, . . . 410Z), enclosure B (sensors 415A, 415B, 415C, 415Z), enclosure C (sensors 420A, 420B, 420C, . . . 640Z), and enclosure Z (sensors 485A, 485B, 485C, . . . 485Z). Communicatively coupled comprises wired and/or wireless communication. In some embodiments, a device ensemble includes at least two sensors of a differing types. In some embodiments, a device ensemble includes at least two emitters of a differing types. In some embodiments, a device ensemble includes at least two sensors of the same type (e.g., a sensor array). In some embodiments, a device ensemble includes at least two emitters of the same type (e.g., an emitter array such as a light emitting diode (LED) array).

In some embodiments, a device ensemble includes at least two sensors of the same type. In the example shown in FIG. 4, sensors 410A, 410B, 410C, . . . 410Z of enclosure A represent an ensemble. An ensemble of sensors can refer to a collection of diverse sensors. In some embodiments, at least two of the sensors in the ensemble cooperate to determine environmental parameters, e.g., of an enclosure in which they are disposed. For example, a device ensemble may include a carbon dioxide sensor, a carbon monoxide sensor, a volatile organic chemical compound sensor, an environmental noise sensor, a light (e.g., visible, UV, or IR) sensor, a temperature sensor, and/or a humidity sensor. A device ensemble may comprise other types of sensors, e.g., as disclosed herein. The enclosure may comprise one or more sensors that are not part of an ensemble of sensors. The enclosure may comprise a plurality of ensembles. At least two of the plurality of ensembles may differ in at least one of their sensors. At least two of the plurality of ensembles may have at least one of their sensors that is similar (e.g., of the same type). For example, an ensemble can have two motion sensors and one temperature sensor. For example, an ensemble can have a carbon dioxide sensor and an IR sensor. The ensemble may include one or more devices that are not sensors. The one or more other devices that are not sensors may include sound emitter (e.g., buzzer), and/or electromagnetic radiation emitters (e.g., light emitting diode). In some embodiments, a single sensor (e.g., not in an ensemble) may be disposed adjacent (e.g., immediately adjacent such as contacting) another device that is not a sensor.

In some embodiments, processing sensor data comprises performing sensor data analysis. The sensor data analysis may comprise at least one rational decision making process, and/or learning. The sensor data analysis may be utilized to adjust an environment, e.g., by adjusting one or more components that affect the environment of the enclosure. The data analysis may be performed by a machine based system (e.g., a circuitry). The circuitry may be of a processor. The sensor data analysis may utilize artificial intelligence. The sensor data analysis may rely on one or more models (e.g., mathematical models). In some embodiments, the sensor data analysis comprises linear regression, least squares fit, Gaussian process regression, kernel regression, nonparametric multiplicative regression (NPMR), regression trees, local regression, semiparametric regression, isotonic regression, multivariate adaptive regression splines (MARS), logistic regression, robust regression, polynomial regression, stepwise regression, ridge regression, lasso regression, elasticnet regression, principal component analysis (PCA), singular value decomposition, fuzzy measure theory, Borel measure, Han measure, risk-neutral measure, Lebesgue measure, group method of data handling (GMDH), Naive Bayes classifiers, k-nearest neighbors algorithm (k-NN), support vector machines (SVMs), neural networks, support vector machines, classification and regression trees (CART), random forest, gradient boosting, or generalized linear model (GLM) technique.

In some embodiments, one or more sensors are added or removed from a community of sensors, e.g., disposed in the enclosure and/or in the device ensemble. Newly added sensors may inform (e.g., beacon) other members of a community of sensor of its presence and relative location within a topology of the community. Examples of sensors, sensor ensembles, sensor community(ies), control system, and network can be found, for example, in International Patent Application Serial Number PCT/US21/12313 that was filed Jan. 6, 2021 titled “LOCALIZATION OF COMPONENTS IN A COMPONENT COMMUNITY,” which is incorporated by reference herein in its entirety. Sensors of a device ensemble may be organized into a sensor module. A device ensemble may comprise at least one circuit board, such as a printed circuit board, in which a number of devices (e.g., sensors and/or emitters) are adhered or affixed to the at least one circuit board. Devices can be removed from the device ensemble. For example, a sensor may be plugged and/or unplugged from the circuit board. Sensors may be individually activated and/or deactivated (e.g., using a switch). The circuit board may comprise a polymer. The circuit board may be transparent or non-transparent. The circuit board may comprise metal (e.g., elemental metal and/or metal alloy). The circuit board may comprise a conductor. The circuit board may comprise an insulator. The circuit board may comprise any geometric shape (e.g., rectangle or ellipse). The circuit board may be configured (e.g., may be of a shape) to allow the ensemble to be disposed in a mullion (e.g., of a window). The circuit board may be configured (e.g., may be of a shape) to allow the ensemble to be disposed in a frame (e.g., door frame and/or window frame). The mullion, transom, and/or frame may comprise one or more holes to allow the sensor(s) to obtain (e.g., accurate) readings. The sensor ensemble may comprise a housing. The housing may comprise one or more holes to facilitate sensor readings. The circuit board may include an electrical connectivity port (e.g., socket). The circuit board may be connected to a power source (e.g., to electricity). The power source may comprise renewable or non-renewable power source.

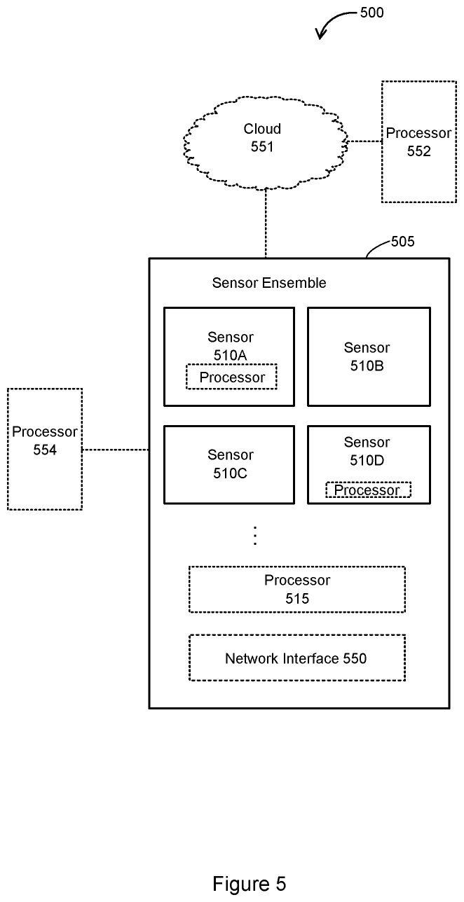

FIG. 5 shows an example of a system 500 including an ensemble of devices organized into a device module. Sensors 510A, 510B, 510C, and 510D are shown as included in a device ensemble 505 (e.g., having a housing). A device ensemble (e.g., the device ensemble 505) may comprise a sensor module that may include at least 1, 2, 4, 5, 8, 10, 20, 50, or 500 devices (e.g., sensors and/or emitters). The device ensemble may include a number of devices in a range between any of the aforementioned values (e.g., from about 1 to about 1000, from about 1 to about 500, or from about 500 to about 1000). Sensors of a device ensemble may comprise sensors configured or designed for sensing a parameter comprising, temperature, humidity, carbon dioxide, particulate matter (e.g., between 2.5 μm and 10 μm), total volatile organic compounds (e.g., via a change in a voltage potential brought about by surface adsorption of volatile organic compound), ambient light, audio noise level, pressure (e.g., gas, and/or liquid), acceleration, time, radar, lidar, radio signals (e.g., ultra-wideband radio signals), passive infrared, glass breakage, or movement. The device ensemble (e.g., 505) may comprise non-sensor devices, such as emitters (e.g., buzzers and/or light emitting diodes). Examples of device ensembles and their uses can be found in U.S. patent application Ser. No. 16/447,169, filed Jun. 20, 2019, titled “SENSING AND COMMUNICATIONS UNIT FOR OPTICALLY SWITCHABLE WINDOW SYSTEMS,” which is incorporated herein by reference in its entirety. In some embodiments, an increase in the number and/or types of sensors is used to increase a probability that one or more measured property is accurate and/or that a particular event measured by one or more sensor has occurred. In some embodiments, sensors of device ensemble and/or of different device ensembles cooperate with one another. In an example, a radar sensor of device ensemble may determine presence of a number of individuals in an enclosure. A processor (e.g., processor 515) may determine that detection of presence of a number of individuals in an enclosure is positively correlated with an increase in carbon dioxide concentration. In an example, the processor-accessible memory may determine that an increase in detected infrared energy is positively correlated with an increase in temperature as detected by a temperature sensor. In some embodiments, a network interface (e.g., 550) communicates with other device ensembles similar to device ensemble 505. The network interface may additionally communicate with a control system. Individual sensors (e.g., sensor 510A, sensor 510D, etc.) of a device ensemble may comprise and/or utilize at least one dedicated processor. A device ensemble may utilize a remote processor (e.g., 554) utilizing a wireless and/or wired communications link. A device ensemble may utilize at least one processor (e.g., processor 552), which may comprise a cloud-based processor coupled to a device ensemble via the cloud (e.g., 551). Processors (e.g., 552 and/or 554) may be located in the same building, in a different building, in a building owned by the same or different entity, a facility owned by the manufacturer of the window/controller/device ensemble, or at any other location. In various embodiments, as indicated by the dotted lines of FIG. 5, device ensemble 505 is not required to comprise a separate processor and network interface. These entities may be separate entities and may be operatively coupled to ensemble 505. The dotted lines in FIG. 5 designate optional features. In some embodiments, onboard processing and/or memory of one or more ensemble of sensors may be used to support other functions (e.g., via allocation of ensembles(s) memory and/or processing power to the network infrastructure of a building). In some embodiments, a plurality of sensors of the same type may be distributed in an enclosure. At least one of the plurality of sensors of the same type, may be part of a device ensemble. For example, at least two of the plurality of sensors of the same type, may be part of at least two ensembles. The device ensembles may be distributed in an enclosure. An enclosure may comprise a conference room. For example, a plurality of sensors of the same type may measure an environmental parameter in the enclosure. Responsive to measurement of the environmental parameter of an enclosure, a parameter topology of the enclosure may be generated. A parameter topology may be generated utilizing output signals from any type of sensor of device ensemble, e.g., as disclosed herein. Parameter topologies may be generated for any enclosure of a facility such as conference rooms, hallways, bathrooms, cafeterias, garages, auditoriums, utility rooms, storage facilities, equipment rooms, and/or elevators.

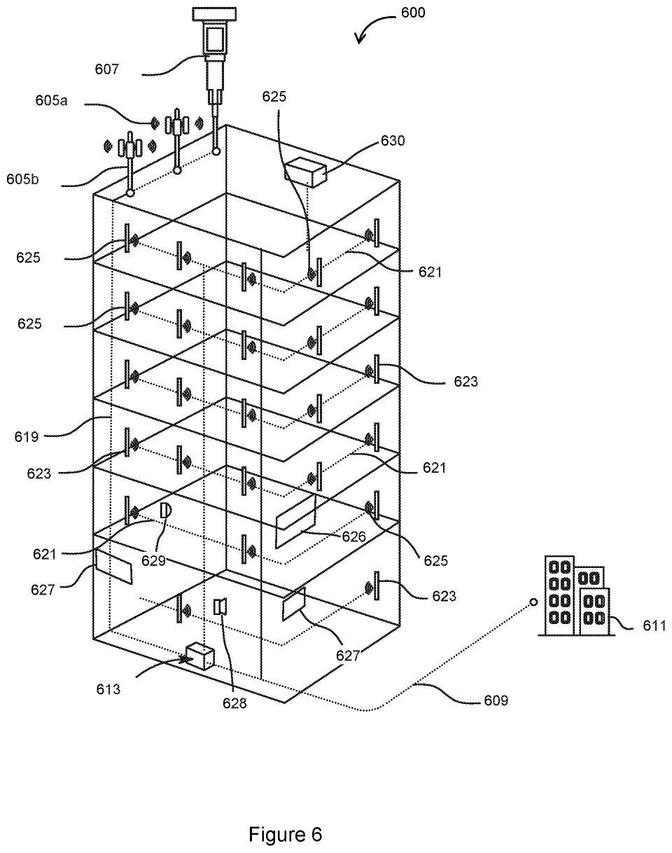

In some embodiments, a building network infrastructure has a vertical data plane (between building floors) and a horizontal data plane (all within a single floor or multiple (e.g., contiguous) floors). In some cases, the horizontal and vertical data planes have at least one (e.g., all) data carrying capabilities and/or components that is (e.g., substantially) the same or similar data. In other cases, these two data planes have at least one (e.g., all) different data carrying capabilities and/or components. For example, the vertical data plane may contain one or more components for fast data transmission rates and/or bandwidths. In one example, the vertical data plane contains components that support at least about 10 Gigabit/second (Gbit/s) or faster (e.g., Ethernet) data transmissions (e.g., using a first type of wiring (e.g., UTP wires and/or fiber optic cables)), while the horizontal data plane contains components that support at most about 8 Gbit/s, 5 Gbit/s, or 1 Gbit/s (e.g., Ethernet) data transmissions, e.g., via a second type of wiring (e.g., coaxial cable). In some cases, the horizontal data plane supports data transmission via d.hn or MoCA standards (e.g., MoCA 2.5 or MoCA 3.0). In certain embodiments, connections between floors on the vertical data plane employ control panels with high speed (e.g., Ethernet) switches that pair communication between the horizontal and vertical data planes and/or between the different types of wiring. These control panels can communicate with (e.g., IP) addressable nodes (e.g., devices) on a given floor via the communication (e.g., d.hn or MoCA) interface and associated wiring (e.g., coaxial cables, twisted cables, or optical cables) on the horizontal data plane. Horizontal and vertical data planes in a single building structure are depicted, e.g., in FIG. 6.

Data transmission, and in some embodiments voice services, are provided in a facility (e.g., comprising a building) (i) via wireless and/or wired communications, and/or (ii) to and/or from occupants of the building. The data transmission and/or voice services may become difficult due in part to attenuation by building structures (such as walls, floors, ceilings, and windows), in third, fourth, or fifth generation (3G, 4G, or 5G) cellular communication. Relative to 3G and 4G communication, the attenuation becomes more severe with higher frequency protocols such as 5G. To address this challenge, a building can be outfitted with components that serve as gateways or ports for cellular signals. Such gateways couple to infrastructure in the interior of the building that provide wireless service (e.g., via interior antennas and other infrastructure implementing Wi-Fi, small cell service (e.g., via microcell or femtocell devices), CBRS, etc.). The gateways or points of entry for such services may include high speed cable (e.g., underground) from a central office of a carrier and/or a wireless signal received at an antenna strategically located on the building exterior (e.g., a donor antenna and/or sky sensor on the building's roof). The high speed cable to the building can be referred to as “backhaul.” The cabling may comprise coaxial or optical cables. The cabling (e.g., coaxial cable) may be configured to transmit power and communication on the same cable. The communication may comprise one or more types of communication. For example, cellular, media, control, and other data (e.g., sensor data) communication. The cellular may conform to at least a 2^{nd} generation (2G), 3G, 4G, and/or 5G communication protocol.

FIG. 6 shows an example of a building 600 with device ensembles 623 (e.g., disposed in a housing). As points of connection, the building includes rooftop donor antennas 605, 605b as well as a sky sensor 607 for sending electromagnetic radiation (e.g., infrared, ultraviolet, and/or visible light). At least some of the wireless signals may allow a building services network to wirelessly interface with one or more communications service provider systems. The building has a control panel 613 for connecting to a provider's central office 611 via a physical line 609 (e.g., an optical fiber such as a single mode optical fiber). The control panel 613 may include hardware and/or software (e.g., non-transitory computer readable medium/media) configured to provide functions of, for example, a signal source carrier head end, a fiber distribution headend, and/or a (e.g., bi-directional) amplifier and/or repeater. The rooftop donor antennas 605a and 605b allow building occupants and/or devices to access a wireless system communications service of a (e.g., 3^{rd} party) provider. The antenna and/or controller(s) may provide access to the same service provider system, a different service provider system, or some variation such as two interface elements providing access to a system of a first service provider, and a different interface element providing access to a system of a second service provider.

As shown in the example of FIG. 6, a vertical data plane may include a (e.g., high capacity, or high-speed) data carrying line 619 such as (e.g., single mode) optical fiber or UTP copper lines (of sufficient gauge). In some embodiments, at least one control panel is provided on at least part of the floors of the building (e.g., on each floor). In some embodiments, one (e.g., high capacity) communication line directly connects a control panel in the top floor with (e.g., main) control panel 613 in the bottom floor (or in the basement floor). Note that control panel 613 directly connects to rooftop antennas 605a, 605b and/or sky sensor 607, while control panel 613 also directly connects to the (e.g., 3^{rd} party) service provider central office 611.

FIG. 6 shows an example of a horizontal data plane that may include one or more of the control panels and data carrying wiring (e.g., lines), which include trunk lines 621. In certain embodiments, the trunk lines are made from coaxial cable. The trunk lines may comprise any wiring disclosed herein (e.g., twisted wire(s)). The control panels may be configured to provide data on the trunk lines 621 via a data communication protocol (such as MoCA and/or d.hn). The data communication protocol may comprise (i) a next generation home networking protocol (abbreviated herein as “G.hn” protocol), (ii) communications technology that transmits digital information over power lines that traditionally used to (e.g., only) deliver electrical power, or (iii) hardware devices designed for communication and transfer of data (e.g., Ethernet, USB and Wi-Fi) through electrical wiring of a building. The data transfer protocols may facilitate data transmission rates of at least about 1 Gigabits per second (Gbit/s), 2 Gbit/s, 3 Gbit/s, 4 Gbit/s, or 5 Gbit/s. The data transfer protocol may operate over telephone wiring, coaxial cables, power lines, and/or (e.g., plastic) optical fiber. The data transfer protocol may be facilitated using a chip (e.g., comprising a semiconductor device). At least one (e.g., each) horizontal data plane may provide high speed network access to one or more device ensembles 623 (e.g., a set of one or more devices in a housing comprising an assembly of devices) and/or antennas 625, some or all of which are optionally integrated with device ensembles 623. Antennas 625 (and associated radios, not shown) may be configured to provide wireless access by any of various protocols, including, e.g., cellular (e.g., one or more frequency bands at or proximate 28 GHZ), Wi-Fi (e.g., one or more frequency bands at 2.4, 5, and 60 GHZ), Citizens Broadband Radio Service (CBRS), and the like. Drop lines may connect device ensembles 623 to trunk lines 621. In some embodiments, a horizontal data plane is deployed on a floor of a building. The devices in the device ensemble may comprise a sensor, emitter, or antenna. The device ensemble may comprise a circuitry. The devices in the device ensemble may be operatively coupled to the circuitry. One or more donor antennas 605a, 605b may connect to the control panel 613 via high speed lines (e.g., single mode optical fiber or copper). In the depicted example, the control panel 613 may be located in a lower floor of the building. Also as depicted, the connection to the donor antenna(s) 605a, 605b may be via one or more radios and wiring (e.g., coaxial cable). The radios may comprise virtualized radio access network (vRAN). The communications service provider central office 611 connects to ground floor control panel 613 via a high speed line 609 (e.g., an optical fiber serving as part of a backhaul). This entry point of the service provider to the building is sometimes referred to as a Main Point of Entry (MPOE). The MPOE may be configured to permit the building to distribute both voice and data traffic.

In some embodiments, devices coupled to the building network (e.g., integrated into device ensembles and/or standalone devices) include interactive devices capable of generating one or more stimuli which are perceptible to personnel (e.g., building occupants and/or other humans). For example, interactive devices may provide information, advertising, and/or other types of stimuli (e.g., sights, sounds, and/or environments), e.g., as disclosed herein. In some embodiments, interactive devices are disposed in a common area of the facility, and an ability to control the content being disseminated using the interactive devices is granted to a content manager or content provider. In some embodiments, the content provided to target personnel is selected based at least in part on contextual information indicative of a relevancy to the interests of the target personnel. For example, for interactive devices incorporate media (e.g., video) display technology embedded between transparent panels, thus forming a media display construct. The content manager and/or provider may request utilization of the surface area of the media display construct to project various media (e.g., for entertainment, educational, alert, medical, messaging, data processing, and/or to conduct a video conference). At times, a user may want to optimize usage of interior space devoted to visualizing the media (e.g., by using the surface of the media display construct). The media may be electronic media and/or optical media. A user may request viewing the media with minimal impact on visibility through the transparent panel (e.g., through the window). The media may be displayed via a media display technology (e.g., matrix of light emitting entities such as LEDs) that is at least partially transparent (e.g., transparent organic LED matrix (TOLED matrix)). At times viewing the media may require a tinted (e.g., darker) backdrop. At times, it may be requested for a content manager or content provider to determine the availability and capabilities of interactive devices as well as the contextual circumstances of personnel in the vicinity of the interactive devices in order to target useful, relevant information, or other stimuli for dissemination to the personnel. Examples of interactive devices may include tintable windows (e.g., electrochromic (EC) window), media displays (e.g., transparent OLED displays construct), touchscreen controllers (e.g., incorporated with, or coupled to, the transparent media displays), sound transducers such as loudspeakers, lighting, heating, cooling, ventilation, or heating ventilation and air conditioning (HVAC) equipment. Examples of stimuli may include disseminated messages (e.g., information or advertisements delivered as visual and/or audible stimuli), personal data (e.g., calendar or appointment data), warnings or alarms (e.g., visual or audible), and environmental conditions (e.g., HVAC adjustments).

In some embodiments, a digital interface is provided that allows a content manager and/or (e.g., 3^{rd} party) content provider to utilize computer systems and/or applications in order to (i) couple to an interactive device in a facility and (ii) engage with the device in a digital experience. For example, content may be personalized for a facility occupant (e.g., a target person) interacting with the system, e.g., via a transparent media display, wherein the content may include advertisement or other information requested by the content manager, by the content provider, and/or anticipated by an artificial intelligence (AI) control system for the target person(s), e.g., based on preferences or other data collected previously or contemporaneously by the control system. Examples of media display constructs, control system, and network, can be found in International Patent Application Serial No. PCT/US20/53641, filed Sep. 30, 2020, titled, “Tandem Vision Window and Media Display,” U.S. patent application Ser. No. 16/950,774, filed Nov. 17, 2020, titled, “DISPLAYS FOR TINTABLE WINDOWS,” U.S. patent application Ser. No. 17/081,809, filed Oct. 27, 2020, titled, “TINTABLE WINDOW SYSTEM COMPUTING PLATFORM,” and U.S. Provisional Patent Application Ser. No. 63/154,352, filed Feb. 26, 2021, titled, “DISPLAY CONSTRUCT FOR MEDIA PROJECTION AND WIRELESS CHARGING,” each of which is incorporated herein by reference in its entirety.

FIG. 6 shows various examples of interactive devices to which targeted personnel may come into contact with while occupying the facility. For example, a large media display construct 626 may include a transparent display matrix for projecting media to occupants on a second floor of building 600. A lighting module 629 projects light signals (e.g., color-coded signals) or projected patterns (e.g., using a scanning laser beam) to interact with the occupants. A ground floor of building 600 includes media display constructs 627 and a sound transducer 628 (e.g., loudspeakers) which may operate separately or in coordination.

In some embodiments, a facility includes interactive devices configured to interact with target person(s), e.g., through a digital experience. The interactive devices being utilized to provide engagement with target personnel may include sensors, emitters, controllers, tintable windows, media displays, light sources, and/or sound transducers. Interactive applications may include controlling tint of windows, interacting with a video display, targeted advertising (e.g., context-based real-time advertising), controlling a sound system, controlling an environmental variable of the enclosure (e.g., by controlling an HVAC), controlling lighting of the enclosure, controlling alarms, controlling ingress/egress gateways (e.g., automatic doors), and/or controlling electrical power. At least one (e.g., each) of the different interactive application may provide corresponding stimuli which are recognizable to the target persons, such as images, sounds, air temperature (e.g., feelings of warmth or cold), air circulation, room illumination (e.g., window tinting), colored lights, freshness of air, scents, and others. Each type of stimuli disseminated by (e.g., projected from) an interactive device may have a corresponding interaction zone where the targeted personnel are able to perceive the stimuli. In some embodiments, a designation of the locations comprising the interaction zone where the stimuli are perceptible by a target person (e.g., an average person) is provided as an isovist. In some embodiments, an isovist is a volume of space which is visible from the location at which the interactive device projects the stimuli (e.g., together with a specification of the point in space where the device is located). For interactive devices emitting other types of stimuli than light, an isovist may correspond to the spaces where the targeted personnel come under the influence of, and are likely to perceive, the stimuli.

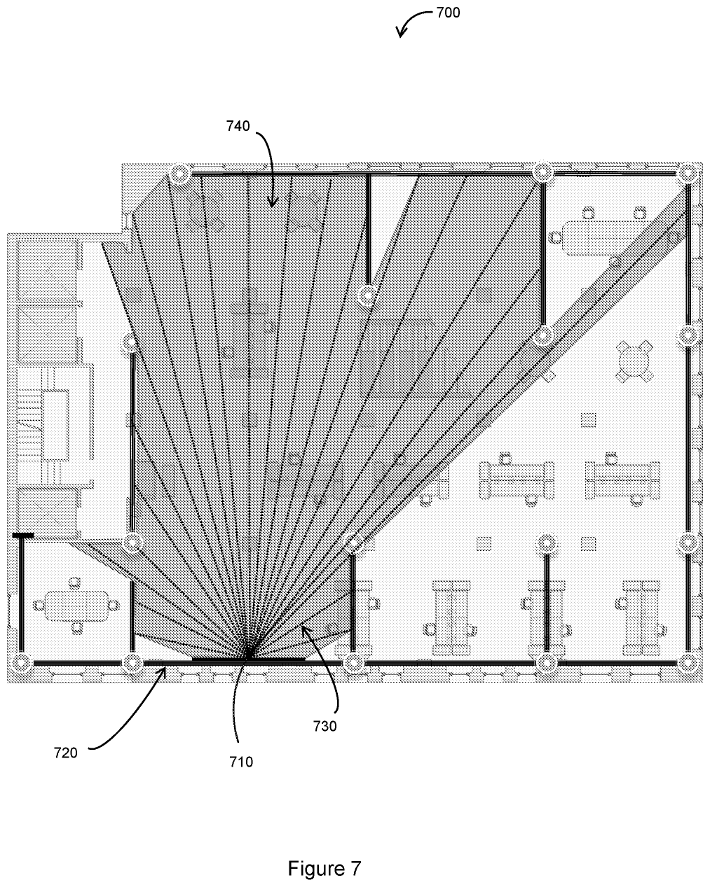

FIG. 7 shows an example of an isovist on a two-dimensional floorplan 700. An interactive device 710 such as a media display construct (e.g., a transparent OLED display construct) is disposed at a wall 720 of a facility. Images produced by interactive device 710 are projected as rays 730 within the facility. Interior fixtures such as walls may interrupt rays 730 at various locations. A set of locations on floorplan 700 from which rays 730 are visible defines an isovist 740, which can be used to designate the interaction zone for interactive device 710 with target personnel.

In some embodiments, a digital experience provided by a content manager (e.g., a system and/or application provider) using an interactive device can be contextualized to the targeted personnel (e.g., either as grouped or individualized), e.g., so that the provided stimuli are geared towards engaging the target person(s) with the interactive device. To enable such an interaction, the content manager and/or provider may depend upon information sources which provide (A) information necessary to interact with the interactive device over a network, and (B) contextual information having (e.g., enhanced) relevance and interest for the targeted personnel. In some embodiments, the content manager is adapted to access a device-oriented database and a context-oriented database. The device-oriented database may cover aspects of the interactive device(s) and its/their state(s). The device data can be comprised of a designation for at least one (e.g., each) interactive device in the device database. The designation may include an identifier of the interactive device, a geographic location of the interactive device, an orientation of the interactive device, and/or a boundary description of a space in which the stimuli are perceptible to the target personnel (e.g., via an isovist). The boundary description may be comprised of an isovist. Device data may comprise controllable and/or interactive capabilities of the device. For example, device data for a media display may include properties of the media display such as size, location, content format allowed, and/or actions allowed (e.g., playback, hide, show, on-actions, rotate, pause, play, forward, fast forward, rewind, fast rewind, etc.). For example, device data for a sound player may include properties such as location, content format allowed, and/or actions allowed (e.g., playback, on-actions, volume, music selection, channel, pause, play, forward, fast forward, rewind, fast rewind, etc.). In some embodiments, the device oriented database (e.g., that is accessible by the network) will provide the content manager's operating system and/or applications relevant technical information regarding the interactive device including a geographic location, purpose of the interactive device at a location (e.g., network hierarchy), technical details, communication & power configuration, and/or format in which the interactive device can interact with the targets. For example, for a media display construct, the device information may include location, purpose of the display construct at a location (e.g., network hierarchy), display size, resolution, communication & power configuration, media format, media source, and/or format in which the display construct can represent information.

In some embodiments, the interactive device may provide targeted content to the target personnel. The context-oriented database may provide environmental and/or transactional data to be pushed to the targeted personnel. In some embodiments, the context-oriented database provides contextual data relating to a stimuli context. The stimuli context may depend upon the kinds of activities or persons existing at the facility where interactive devices are located. Depending on the context, contextual data (e.g., stimuli) disseminated to a targeted personnel may be a message. The message may be a commercial message, a health related message, a security related message, an educational message, an entertaining message, an informative message. The message may be regarding the facility status, directions to destinations in the facility, activities in the facility, activities that the facility furthers (e.g., transportation to a destination such as boat ride, train ride, bus rides, or flight). Different interaction zones (e.g., pertaining to different interactive devices in a facility) may have different contexts such that a location of targeted personnel may be tracked by the content manager and/or provider in order to deliver matching contextual data to a corresponding interactive device capable of engaging the targeted personnel. In some embodiments, the functions of identifying a stimuli context and obtaining contextual data are provided by a content manager and/or content provider (e.g., an owner, lessor, manager, and/or messenger of the facility). Identifying the stimuli context and obtaining the contextual data may be performed by a third party, a media outlet, a commercial outlet, a security outlet, or a health outlet. At least one target personnel for receiving the contextual stimuli may comprise a target personnel that is presently at the interaction zone and/or that is projected to be in the interaction zone at a (e.g., determinable) future time. A location of the target personnel at a future time may be determined using geo-location data (e.g., obtained from a mobile circuitry such as an ID tag or a mobile device), a path projection, and/or an electronically-stored schedule or calendar of the target personnel.

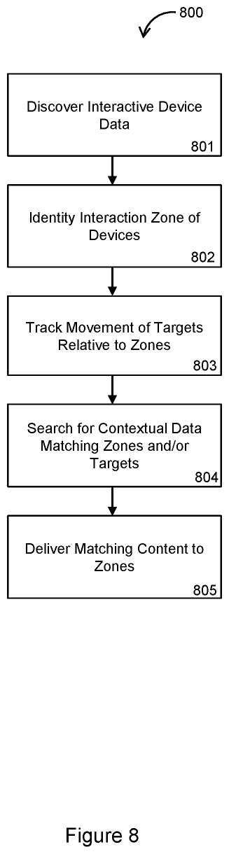

FIG. 8 shows a flowchart of an example method 800 in which a content manager or content provider (e.g., user) discovers interactive device data in an operation 801. The device data enables the user to determine what interactive devices are available, what their capabilities are, and how to link with the interactive devices using network links. In operation 802, interaction zones of the interactive device(s) are identified. In operation 803, the movement of target personnel is tracked in the facility relative to the identified interaction zones. When a targeted personnel is determined to have a matching interaction zone (e.g., already located in a particular zone or projected to enter the particular zone), a search is conducted for contextual data in operation 804. When contextual data is found (e.g., using the context-oriented database) for targeted personnel within an interaction zone (e.g., for an interactive device discovered using the device-oriented database), the matching stimuli are disseminated in the interaction zone in operation 805.

In some embodiments, contextualized targeted information is directed at various levels of precision. For example, targeted personnel information may include (i) information on a group of individuals present at, or heading to, a location, (ii) an aggregate of information on everyone in the facility, (iii) an aggregate of information on everyone in a location of the facility, (iv) an aggregate of information on everyone coming for a specific purpose to the facility (e.g., going to a destination in the facility), and/or (v) individualized information on an individual interacting with the interactive device (e.g., media display).

In some embodiments, the device-oriented database resides in a hierarchical network within, or associated with, a particular facility (e.g., comprising a building, or a boat). A controller system of the facility may provide links to the device database, a plurality of interactive devices, and tracking devices for monitoring locations of targeted personnel. In some embodiments, a content manager and/or content provider is located remotely (e.g., cloud-based) from the facility having the interactive devices. The content manager and/or provider may remotely accesses the device-oriented database and tracking data of the targeted personnel, e.g., using a database input configured by the facility control system. One or more of the databases may be remove (e.g., cloud based). For example, the context-oriented database may be cloud-based (e.g., in order to facilitate third party maintenance of its content). One or more of the databases may be local. For example, the context-oriented database may be located on the premises in the facility network.

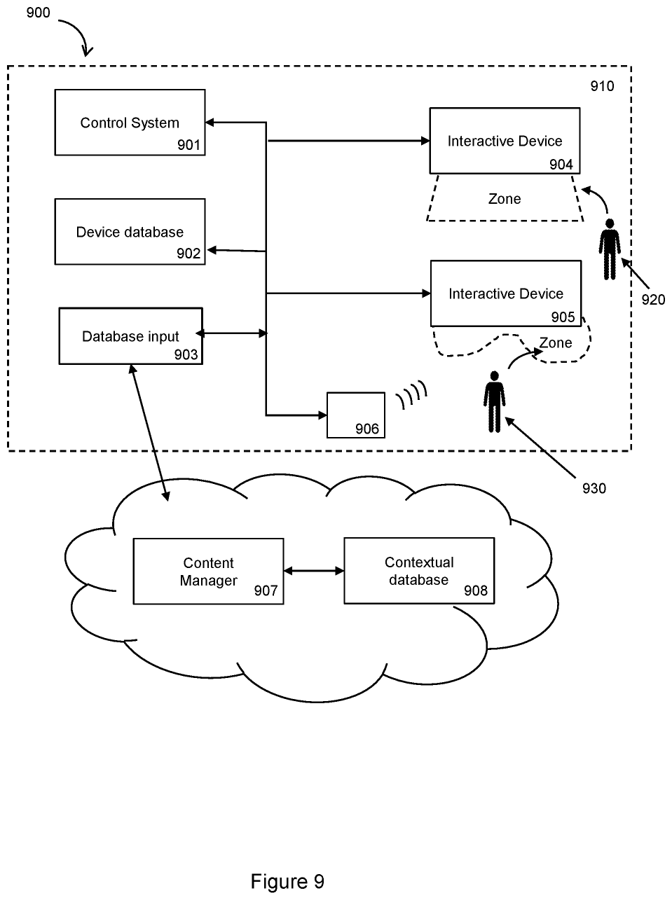

FIG. 9 shows an example engagement system 900 at least partly disposed in a building 910. A (e.g., hierarchical) controller system 901 (e.g., including a master controller) is linked with a device-oriented database 902. A database input 903 may be comprised of a gateway for linking controller system 901 with a cloud network 950. Interactive devices 904 and 905 in facility 910 have respective interaction zones that may be occupied presently or in the future by targeted personnel 920 or 930. The present locations of personnel 920 and 930 are monitored using a geo-location tracking component 906. For example, an ultrawideband (UWB) locator node for tracking ID badges having UWB tags or a cellular transceiver for monitoring users' cellphones. A contextual database 908 is located in cloud 950 with a content manager client 907. In order to perform tasks selected by a content manager and/or provider, client 907 can access databases 902 and 908 to identify available interactive devices and contextual data (e.g., respectively) to be disseminated to targeted personnel 920 and/or 930.

In some embodiments, the interactive devices are comprised of media displays for projecting media, e.g., as video images. The media display constructs may be integrated with, or coupled to, tintable windows. The projected media may be in the form of messages presented according to the capabilities of, and the format used by, the media display construct. To correctly access the media display constructs, device data needed by the content manager may be made available by the device-oriented database, e.g., using a data format or language (e.g., a markup programming language) in a convenient and easily managed fashion. The language may facilitate the discovery of data regarding addressability of the interactive device by a content manager and/or content provider (e.g., 3^{rd} party) operating system (OS). Interactive device data may preferably utilize (i) standard device parameter definitions (e.g., programmability of interactive device(s) comprising an electrochromic window, music player, lighting, HVAC system, or media display construct) and (ii) standard discovery protocols (e.g., device identification format), as defined in conjunction with the programming language. The programming language may provide an open system for interaction between the content manager and/or content provider (e.g., 3^{rd} party) computer systems (OS), with the interactive device(s). A seamless coupling and interacting with selected interactive devices may be obtained (e.g., plug & play, and/or wireless coupling). The interactive device may comprise an output device comprising a light source, sounds source, smell source, gas source, HVAC outlet, cooler, vent, or heater. The interactive device may project audio and/or visual media (e.g., stills or moving pictures). The interactive device may be operatively coupled to at least one input source comprising a virtual reality input source, a keyboard, a touch screen, a microphone, a drawing pad (e.g., using a stylus), a visual sensor, or any other time of sensor (e.g., as disclosed herein). The sensor may be configured to sense any human sense. For example, a visual, auditory, olfactory, gustatory, or tactile sensor. The sensor may be configured to sense the vestibular or proprioceptive system. The sensor may comprise a temperature sensor. The sensor may comprise a gas sensor, an optical sensor, or a particulate matter sensor.

In some embodiments, an interactive device (e.g., dynamic device) markup programming language is employed having objects with associated properties. They interactive device makeup programming language may comprise a computer language that uses tags to define elements within a document, e.g., hyper-text makeup language (HTML) or Extensible Markup Language (XML). An object in the language can be associated with any interactive device as in a standard markup language (e.g., a JSON structure). The interactive device may comprise a sensor, emitter, controller, tintable window, speaker, lighting, HVAC system, alarm system, sanitation system, medical system, educational system, monetary system, automatic door, automatic window, or media display). For example, an interactive device such as a display construct may be represented by an object having properties (e.g., size, location, content format allowed, action allowed (e.g., playback, hide, show, on-actions, rewind, rotate, etc.), and other capabilities, e.g., as disclosed herein. Once a device is discovered and its properties (e.g., specification) retrieved, the device may be accessed in any (e.g., 3^{rd} party) OS, application and/or program to which it is operatively coupled. For example, the interactive device may facilitate access of an advertisement exchange, a content management system, an alert system, and/or a building automation system.

In some embodiments, a user operatively couples to the interactive device. Coupling of a user OS to the interactive device via “plug & play” and/or wireless coupling capability may be achieved using an interactive device identification format, which may be defined for at least one (e.g., any) OS (e.g., 3^{rd} party) to automatically detect the interactive device. The content manager and/or content provider (e.g., the 3^{rd} party) can query the interactive device for its capabilities (using the markup language). Once detected (e.g., via the network), the OS may apply various applications to interact with the interactive device. The applications may allow plug & play of the content manager and/or content provider (e.g., 3^{rd} party) device to the network that includes the interactive device. For example, a dynamic window identification format may be defined for any (e.g., 3^{rd} party) OS to automatically detect dynamic windows, and then the OS may query a media display construct for its capabilities (e.g., using the markup language). Once detected (e.g., via the network), the OS may apply various applications to interact with the interactive device (e.g., media display construct) allowing plug & play of delivered content (e.g., projected media) from the content manager and/or content provider device to the network that includes the interactive device.

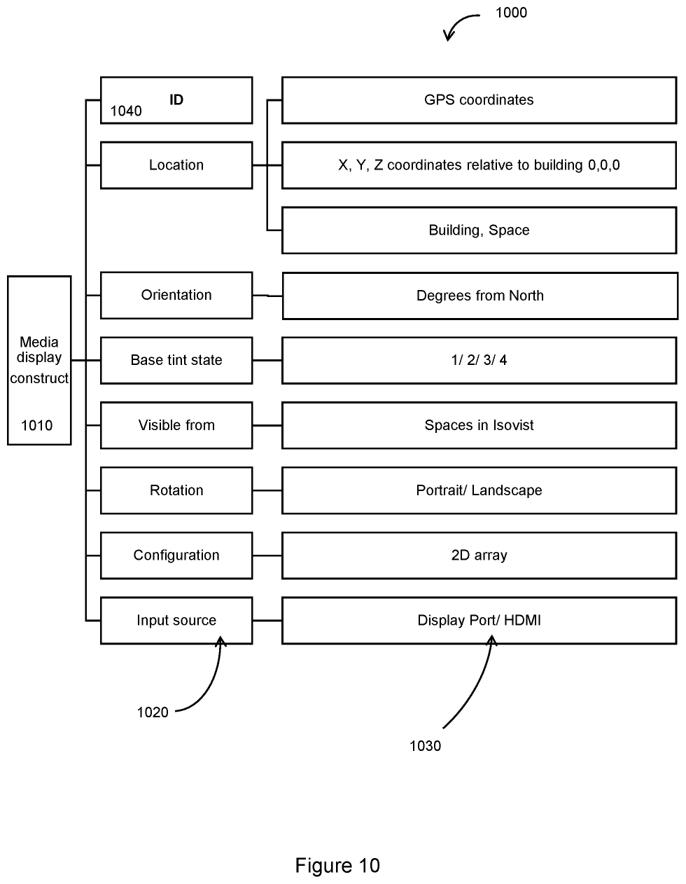

FIG. 10 shows an example markup language representation 1000 corresponding to an interactive device that is in this example, a media display construct 1010. Representation 1000 includes a plurality of identifier tags 1020, some of which may have one or more object properties 1030. A device ID 1040 may be utilized for identification of the media display construct utilized in the local controller network of the facility (e.g., a SetID). Using representation 1000, static and/or dynamic information may be linked to the media display to provide contextual content. A location tag may provide a location of the device in terms of its geolocation (e.g., in Global Positional System (GPS) coordinates, radial coordinates, Cartesian coordinates (e.g., relative to a facility origin x,y,z=0,0,0), or another facility/space definition). A projection orientation tag may provide a spatial orientation and/or location of the display, e.g., in relative terms such as degrees from North. A tint tag may be provided for a tintable window to which the media display construct is associated with. The tint state of the tintable window may have a value according to a distinct tint states, such as one out of four levels. In some embodiments, representation 1000 includes interactive device data, e.g., comprising a designation of the interaction zone with potential target personnel. For an interactive device that is a display construct, the interaction zone may comprise spaces or locations from which the projected media is visible. For example, the designation may comprise an isovist corresponding to the stimuli of the interactive device (e.g., visual of the media display construct perceived by the target personnel). The space contained in an isovist may be delineated according to a defined spatial boundary, e.g., using a set of rays projecting at specified directions and distances, or using other geographic and/or geometric descriptions. An aspect orientation tag may indicate whether a media display construct is shown in portrait or landscape mode, and/or may provide a display resolution. A configuration tag may specify whether an array of media display construct units are arranged (e.g., as a matrix) to work as a two-dimensional array to project a coordinated media (e.g., as coordinated video wall, as coordinated duplicate displays, or as uncoordinated media display constructs). An input source tag may provide technical properties such as whether a display is configured to use a Display Port type of input or HDMI.

In some embodiments, a content manager and/or content provider engages at least one target personnel in a facility with targeted stimuli, after first obtaining device data from a device database that associates (i) an interactive device with (ii) an interaction zone and with (iii) a stimuli of the interactive device disposed in the facility. The content manager and/or content provider may identify a stimuli context that is pertinent to at least one target personnel presently at the interaction zone and/or is projected to be in the interaction zone at a future time. The content manager and/or content provider may obtain contextual data relating to the stimuli context from a contextual database. The content manager and/or content provider may (e.g., then) use the interactive device to disseminate the contextual data to the interaction zone, using the interactive device. For example, the content manager and/or provider may select goods, services, or any selected information to be promoted for any purpose suitable to the content manager and/or provider. The content manager and/or provider may identify an input information (or other stimuli) that is relevant for being disseminated (e.g., promoted) by the interactive device, to achieve the desired purpose. For example, contextual data may be disseminated using stimuli from an interactive device in the form of a message using projected media from a media projector. Such a message may comprise a commercial message, a health related message, a security related message, an informative message (e.g., regarding the facility), an informative message regarding activities (e.g., in the facility), and/or any other message disclosed herein. The facility may comprise a transportation hum, a monetary institution, a health institution, a sport institution, a hospitality institution, a dining institution, a social institution, a wellness related institution, a retail establishment, an entertainment establishment, an educational institution, a recreational institution, a commercial setting, a work place, a storage facility, or a production facility. For example, the facility may comprise an airport, a bank, a hospital, a sport arena, a hotel, a club, a restaurant, a country club, a resort, a mall, a shop, a theater, a transportation terminal, a school, a museum, an office, a gym, a warehouse, or a factory. The content manager and/or provider may identify locations, destinations, and/or paths within the facility for which the contextual data (e.g., stimuli) are relevant. For example, to promote a restaurant or other food service in a facility, locations at and around the restaurant may be relevant for promoting a menu, food type, and/or theme of the restaurant as associated with its name and/or logo. The content manager and/or provider may identify one or more interaction zones for nearby interactive devices in order to find zones (e.g., an isovist) that overlaps with the relevant locations. Then the message (or other stimuli) associated with the goods, services, or any other targeted information, can be projected or emitted using the interactive device(s), to reach targeted personnel who may enter the identified locations, destinations, and/or paths (e.g., that are included in the isovist(s) of the interactive device(s)). In some embodiments, tracking of specific targeted personnel is not required, e.g., since the purpose of presenting a message is to direct the message to all personnel in a designated area.

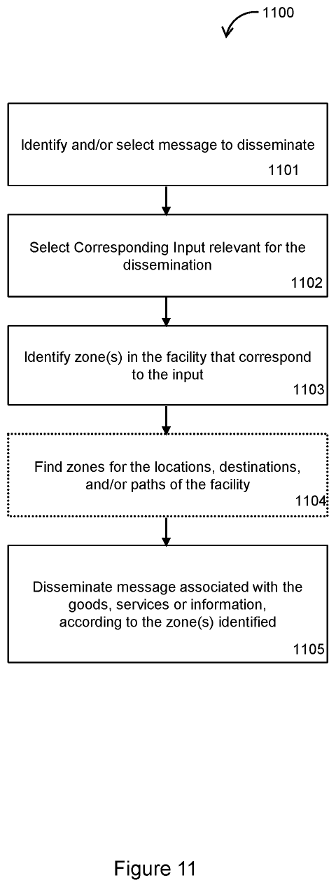

FIG. 11 shows an example flowchart for operations 1100 of directing contextual stimuli to an interaction zone, e.g., regardless of a specific identity of targeted personnel. One or more messages to be disseminated by the interactive device is identified and/or selected in operation 1101. The one or more messages can relate to one of more goods, services, or pieces of information to be promoted. In operation 1102, contextual data is selected as a corresponding input which is relevant for the message. In operation 1103, at least one zone is identified and/or selected in the facility, which zones potentially include target personnel for the interactive device. The zone(s) can include locations, destinations, and/or pathways in the facility, which correspond to the contextual input data. Isovist can be utilized to identify the zone(s). The content manager and/or provider finds interaction zones (e.g., for the locations, destination, and/or paths) in operation 1104, according to designations of the interactions zones (e.g., based at least in part on an isovist for the interactive device, floorplans of the facility, and/or occupancy plan for the facility). In operation 1105, the message to be disseminated (e.g., promoted media that may include information such as advertisements) is projected and/or emitted by the interactive device. The message may be for the associated good, services, or other promoted information to be perceived by targeted personnel in the location, destination, paths, corresponding isovists, facility plan(s), and/or facility schedule(s).

In some embodiments, a specific identity or specific circumstances related to a targeted personnel is included as part of the context used to identify the contextual data of the message to be disseminated. The facility may be a transportation hub (e.g., comprising an airport, train stations, or bus station). For example, a potentially targeted personnel may be a passenger who presents a boarding pass to be scanned (e.g., at an airport), so that a travel destination of the passenger becomes known to the building network. The network may then have, at a minimum, the location information of the passenger and the passenger's destination. The network may also acquire personal information such as the name of the individual and/or a governmental ID of the individual. The network may be a secure (e.g., encrypted) network. The network may be configured to retain the destination information. The network may be configured to exclude personal, sensitive, confidential, and/or privileged information (e.g., governmental ID, name, facial features, birthdate, or any combination thereof). For example, the network may identify the passenger as entering the facility at a certain time, at a certain location, and/or with a certain destination. Using the passenger-specific information, the interactive devices (e.g., media display constructs) along a path through the terminal and/or gate may be used to present the passenger with information regarding the expected passenger flight and/or destination. Personal preferences of the target personnel may be retrieved from a database. For example, in the event that a mobile circuitry (e.g., cell phone, pad, or laptop) of the target personnel (e.g., passenger) may couple to the airport network (e.g., using Wi-Fi or Citizens Broadband Radio Service (CBRS)), then various personal preferences of the personnel may be retrieved. The interactive devices may present information (e.g., advertisements) with an attempt to engage (e.g., target) the passenger. The interactive deice may be used as a digital marketing tool. In some embodiments, the facility is a governmental building, hospital, office, or other entity for which a person's identity and/or purpose for visiting are discoverable (e.g., and are relevant). For example, in a governmental building, a visitor's ID badge may be scanned. In a hospital, an admitted patient may be registered with the hospital and then tracked using various wireless devices and/or sensors. Examples of secure network, messaging scheme, control network, and nodes (e.g., devices such as targeting devices) can be found in U.S. Provisional Patent Application Ser. No. 63/121,561 filed Dec. 4, 2020, titled “ACCESS AND MESSAGING IN A MULTI CLIENT NETWORK,” that is incorporated herein by reference in its entirety.

According to more detailed examples, a company may want to run targeted advertisement on media display constructs at one or more airports where the company operates select stores selling certain goods. A goal of the company may be to target people going to cold places (e.g., to promote respective equipment and/or apparel sold by the select stores). In such a case, the content manager and/or provider may access the context-oriented database to select destinations that are currently cold (e.g., per comparison with weather input such as from the airport or from a 3^{rd} party) and then identify flights going to the designations. The gates corresponding to these flights may also be identified in order to determine locations and/or pathways (e.g., where the targeted personnel may be presently or in a projectable future passing through) for projecting relevant advertisements. In some embodiments, the targeted personnel may be tracked, and the projected the targeting media. Projecting the targeting media may be dynamically controlled, e.g., as the targeted personnel move into associated interaction zones (e.g., into isovists of the interactive device such as a media display construct).

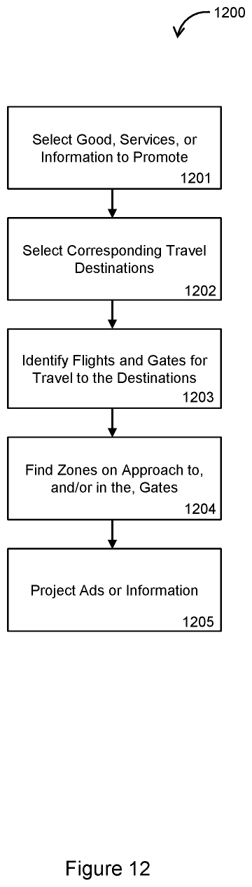

FIG. 12 shows an example flowchart of operations 1200 for projecting ads and/or information in a facility comprising an airport. Goods, services, or other information (e.g., messages such as weather forecasts and/or news items) to be promoted are selected in operation 1201. Travel destinations for which the promoted items are related may be selected (e.g., by the content manager and/or service provider) in operation 1202. In operation 1203, upcoming flights to the destinations and the corresponding gates are identified. Interaction zones (e.g., defined by an isovist, schedule, and/or a floorplan), which coincide with an approach to, or a presence at, the identified gate(s), are determined in operation 1204. In operation 1205, the contextual-data based ads or information are projected (e.g., disseminated) as projected media which is perceptible to targeted personnel. In some embodiments, projection of a particular advertisement is timed according to a location of a targeted personnel who is being tracked. In some embodiments, projection of a particular advertisement is done without respect to the position of any one particular individual.

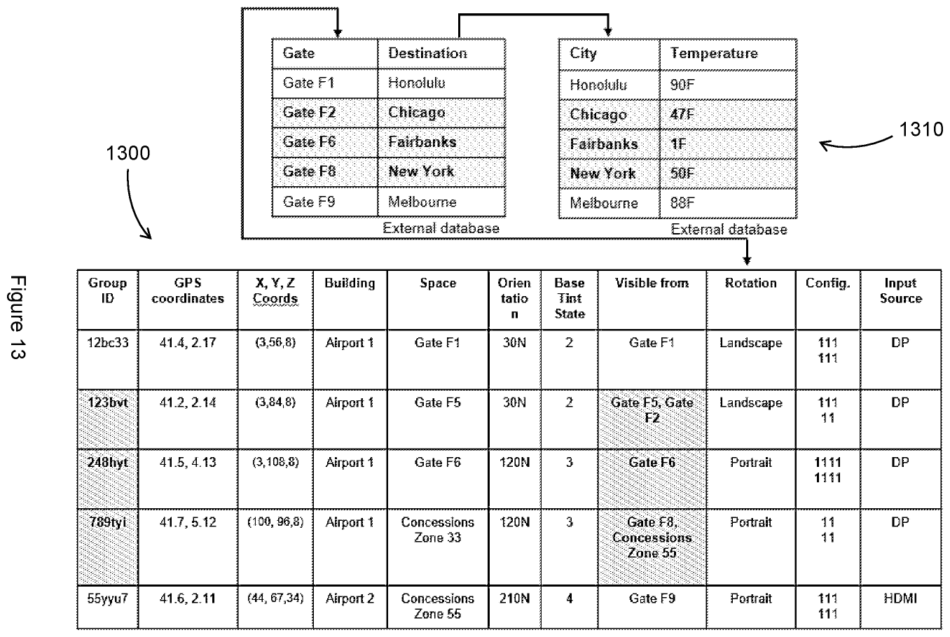

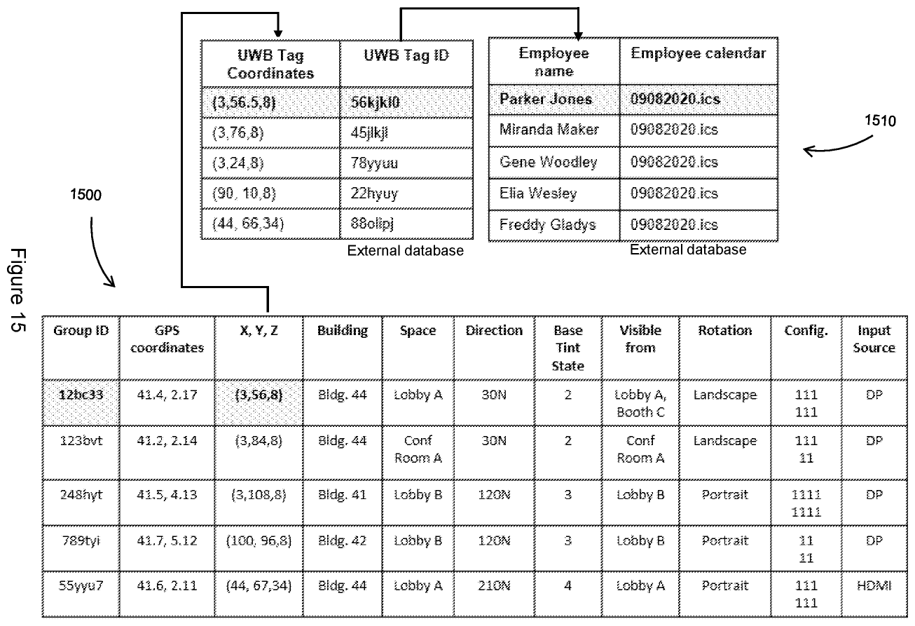

FIG. 13 shows examples of contents of a device-oriented database 1300 and a context-oriented database 1310 for the airport example. Each row of device-oriented database 1300 represents a media display construct or array of media display constructs (represented as a matrix in the “config.” column) at respective locations in the airport. A group ID may be indicative of a type of device (e.g., type of stimuli) as well as a networking address for reaching the device. A designation of the interaction zone may be comprised of regions of the airport as defined by, and named on, a stored floorplan (e.g., using a Revit file, AutoCAD file, or a Scalable Vector Graphics (SVG) formatted file). One or more context-oriented databases 1310 are populated by dynamically changing data such as the destination cities of flights scheduled to leave respective gates as well as data providing current temperatures at the destination cities. In FIG. 13, two databases are shown. The “Base Tint State” column indicated in FIG. 15 represents tint of windows in the space (e.g., tintable windows associated with the matrix of display constructs); the “Rotation” column indicates orientation of the display constructs forming the matrix, “Config.” column indicates configuration of display construct matrix. “Input Source” column indicates the format of media input to the matrix of display constructs.

In some embodiments, at least one interactive device is operated in coordination with at least one other device, which devices are coupled to the network. Control of the at least one device may be via Ethernet. For example, a tint level of tintable windows may be adjusted concurrently. For example, loudspeaker may be activated concurrently. For example, display constructs in a zone may project concurrently. When the devices are in use, devices in the zone may have at least one characteristics that is the same. For example, when the tintable windows are in a zone, a zone of tintable windows may have its tint level (automatically) altered (e.g., darkened or lightened) to the same level. For example, when sounds emitters are in a zone, they may emit the same sound and/or emit at the same time frame. The devices in the zone may comprise a plurality of devices (e.g., of the same type). The zone may comprise (i) devices (e.g., tintable windows) facing a particular direction of an enclosure (e.g., facility), (ii) a plurality of devices disposed on a particular face (e.g., façade) of the enclosure, (iii) devices on a particular floor of a facility, (iv) devices in a particular type of room and/or activity (e.g., open space, office, conference room, lecture hall, corridor, reception hall, or cafeteria), (v) devices disposed on the same fixture (e.g., internal or external wall), (vi) devices that are user defined (e.g., a group of tintable windows in a room or on a façade that are a subset of a larger group of tintable windows, (vii) devices having the same (or overlapping) isovists, (viii) devices targeting the same group of personnel, (xi) devices located along personal transit paths path(s) to the same destination and/or (xii) by functionality of the space in which device(s) are disposed in. The (automatic) control (e.g., adjustment) of the devices may done automatically and/or by a user. For example, the automatic changing of device properties and/or status in a zone, may be overridden by a (e.g., designated or select) user. For example, by manually adjusting the tint level of the tintable window, by manually adjusting the volume level of a loudspeaker, or by manually adjusting the temperature level of an HVAC system. A user may override the automatic adjustment of the devices in a zone using mobile circuitry (e.g., a remote controller, a virtual reality controller, a cellular phone, an electronic notepad, a laptop computer and/or by a similar mobile device).

In some embodiments, one or more databases are utilized to direct the targeting stimuli (e.g., message) to the interactive device. At least two of the databases may be inked. At least two of the databases may feed upon each other's data. At least two of the databases may funnel into a third database. In some embodiments, at least two of the databases are not directly linked. Data from at least two databases may be manipulated (e.g., using logic such as embedded in a software) on its way to the interactive targeting device. The manipulation may include integration and/or analysis of the data. According to an example of contextually relevant data, an operator and/or manager of an office setting may request to greet employees entering an office lobby with their name and the day's calendar entries. For example, a network controller may retrieve name information of an employee, e.g., according to their scanned ID upon entry. A context-oriented database may include an office-wide scheduling system, allowing the day's calendar entries for the employee identified by the scanned ID to be retrieved, and projected media (e.g., an audio message or a visual display) may be used to disseminate the information to the target employee. For improved response times, a control system may prepare greetings and associated daily summary information in advance. A plurality of greetings may be prepared, one for each expected employee containing their corresponding calendared tasks and/or other daily information. A higher hierarchy (e.g., main) controller of the control system may send each greeting to a local controller at each of the potential entry spaces where a respective employee could enter the facility. When a corresponding employee ID tag is read at an entry space, the respective greeting can be initiated (e.g., sounded and/or displayed).

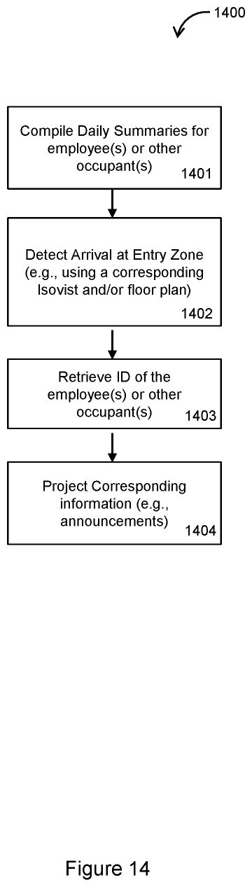

FIG. 14 shows an example flowchart 1400 of a process for engaging employees with office greetings. In an operation 1401, daily summaries are compiled for employees or other regular occupants of a facility. Arrival of a targeted personnel (e.g., employee or occupant) at an entry zone is detected in operation 1402. The entry zone may correspond to an interaction zone of an interactive device overlapping a facility (e.g., building) space that is traversed by people entering the facility, and which has a badge reader determining identify of the person who is entering. The ID of the employee is retrieved in operation 1403. Based at least in part on the ID, the interactive device(s) present, the corresponding information (e.g., meetings and announcements) that is projected to the targeted employee in operation 1404. The control system may compile personal daily summaries (e.g., per person, e.g., according to the person's calendar). The daily summary may be presented by the interactive device, e.g., on entry of the person. The dissemination of information by the interactive device may be automatic (e.g., controlled by the control system), or manual (e.g., the person may choose an announcement type). Preference of the person may be stored in a personalized database, e.g., to alleviate a daily selection requirement from the person. The person may be able to override the previous selection and/or default preference.

FIG. 15 shows examples of contents of a device-oriented database 1500 and a context-oriented database 1510 for the office greeting example. Each row of device-oriented database 1500 represents a media display (or array of media displays) at respective locations in the office (e.g., lobbies). A group ID may be indicative of a type of interactive device (e.g., type of stimuli emitted) and/or a networking address for reaching the interactive device. A designation of the interaction zone may be comprised of regions of the office as defined by, and named on, a stored floorplan (e.g., Revit file, AutoCAD file, or SVG file). Context-oriented database 1510 can be populated by static and/or dynamically changing data such as employee geo-location UWB tag IDs, employee names, employee calendar entries, or any combination thereof. The “Base Tint State” column indicated in FIG. 15 represents tint of windows in the space (e.g., tintable windows associated with the matrix of display constructs); the “Rotation” column indicates orientation of the display constructs forming the matrix, “Config.” column indicates configuration of display construct matrix. “Input Source” column indicates the format of media input to the matrix of display constructs.

Another example of promoted information may include dissemination of environmental quality information, such as levels of pollutants or particulate matter for nearby areas or for travel destinations relevant to targeted personnel. Environmental quality information may be based on Cartesian (XYZ) coordinates of a display or of a device ensemble interconnected with a facility network and/or based at least in part on local weather reports (e.g., using geo location information such as GPS coordinates, UWB tags, Bluetooth information, etc.). In another example, a color scheme of a media display may be altered based at least in part on a time of day (e.g., using geo location information of the facility), e.g., to align with a targeted viewer's circadian rhythms. For example, projected media may be brighter during the day and dimmer during the night. In yet another example, projection of targeted ads may be made contingent upon occupancy thresholds (e.g., using a particular media display at a certain location only when an occupancy sensor associated with the media display senses a threshold number of occupants in a targetable zone).

In some embodiments, the interactive device is operatively coupled to a control system (e.g., comprising a controller). The controller may monitor and/or direct (e.g., physical) alteration of the operating conditions of the apparatuses, software, and/or methods described herein. Control may comprise regulate, manipulate, restrict, direct, monitor, adjust, modulate, vary, alter, restrain, check, guide, or manage. Controlled (e.g., by a controller) may include attenuated, modulated, varied, managed, curbed, disciplined, regulated, restrained, supervised, manipulated, and/or guided. The control may comprise controlling a control variable (e.g., temperature, power, voltage, and/or profile). The control can comprise real time or off-line control. A calculation utilized by the controller can be done in real time, and/or off line. The controller may be a manual or a non-manual controller. The controller may be an automatic controller. The controller may operate upon request. The controller may be a programmable controller. The controller may be programed. The controller may comprise a processing unit (e.g., CPU or GPU). The controller may receive an input (e.g., from at least one sensor). The controller may deliver an output. The controller may comprise multiple (e.g., sub-) controllers. The controller may be a part of a control system. The control system may comprise a master controller, floor controller, local controller (e.g., enclosure controller, or window controller). The controller may receive one or more inputs. The controller may generate one or more outputs. The controller may be a single input single output controller (SISO) or a multiple input multiple output controller (MIMO). The controller may interpret the input signal received. The controller may acquire data from the one or more sensors. Acquire may comprise receive or extract. The data may comprise measurement, estimation, determination, generation, or any combination thereof. The controller may comprise feedback control. The controller may comprise feed-forward control. The control may comprise on-off control, proportional control, proportional-integral (PI) control, or proportional-integral-derivative (PID) control. The control may comprise open loop control, or closed loop control. The controller may comprise closed loop control. The controller may comprise open loop control. The controller may comprise a user interface. The user interface may comprise (or operatively coupled to) a keyboard, keypad, mouse, touch screen, microphone, speech recognition package, camera, imaging system, or any combination thereof. The outputs may include a display (e.g., screen), speaker, or printer.

The methods, systems and/or the apparatus described herein may comprise a control system. The control system can be in communication with any of the apparatuses (e.g., sensors) described herein. The sensors may be of the same type or of different types, e.g., as described herein. For example, the control system may be in communication with the first sensor and/or with the second sensor. The control system may control the one or more sensors. The control system may control one or more components of a building management system (e.g., lighting, security, and/or air conditioning system). The controller may regulate at least one (e.g., environmental) characteristic of the enclosure. The control system may regulate the enclosure environment using any component of the building management system. For example, the control system may regulate the energy supplied by a heating element and/or by a cooling element. For example, the control system may regulate velocity of an air flowing through a vent to and/or from the enclosure. The control system may comprise a processor. The processor may be a processing unit. The controller may comprise a processing unit. The processing unit may be central. The processing unit may comprise a central processing unit (abbreviated herein as “CPU”). The processing unit may be a graphic processing unit (abbreviated herein as “GPU”). The controller(s) or control mechanisms (e.g., comprising a computer system) may be programmed to implement one or more methods of the disclosure. The processor may be programmed to implement methods of the disclosure. The controller may control at least one component of the forming systems and/or apparatuses disclosed herein.

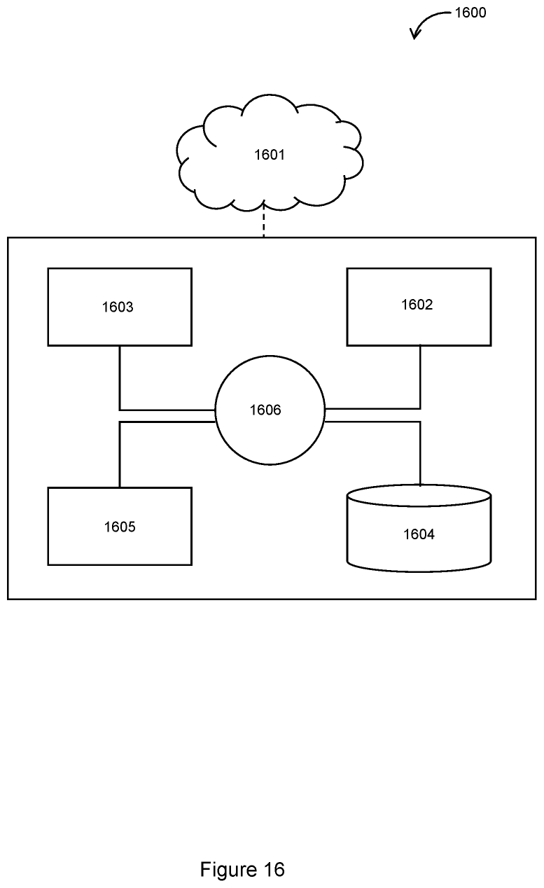

FIG. 16 shows a schematic example of a computer system 1600 that is programmed or otherwise configured to one or more operations of any of the methods provided herein. The computer system can control (e.g., direct, monitor, and/or regulate) various features of the methods, apparatuses and systems of the present disclosure, such as, for example, control heating, cooling, lightening, and/or venting of an enclosure, or any combination thereof. The computer system can be part of, or be in communication with, any sensor or sensor ensemble disclosed herein. The computer may be coupled to one or more mechanisms disclosed herein, and/or any parts thereof. For example, the computer may be coupled to one or more sensors, valves, switches, lights, windows (e.g., IGUs), motors, pumps, optical components, or any combination thereof.

The computer system can include a processing unit (e.g., 1606) (also “processor,” “computer” and “computer processor” used herein). The computer system may include memory or memory location (e.g., 1602) (e.g., random-access memory, read-only memory, flash memory), electronic storage unit (e.g., 1604) (e.g., hard disk), communication interface (e.g., 1603) (e.g., network adapter) for communicating with one or more other systems, and peripheral devices (e.g., 1605), such as cache, other memory, data storage and/or electronic display adapters. In the example shown in FIG. 16, the memory 1602, storage unit 1604, interface 1603, and peripheral devices 1605 are in communication with the processing unit 1606 through a communication bus (solid lines), such as a motherboard. The storage unit can be a data storage unit (or data repository) for storing data. The computer system can be operatively coupled to a computer network (“network”) (e.g., 1601) with the aid of the communication interface. The network can be the Internet, an internet and/or extranet, or an intranet and/or extranet that is in communication with the Internet. In some cases, the network is a telecommunication and/or data network. The network can include one or more computer servers, which can enable distributed computing, such as cloud computing. The network, in some cases with the aid of the computer system, can implement a peer-to-peer network, which may enable devices coupled to the computer system to behave as a client or a server.

The processing unit can execute a sequence of machine-readable instructions, which can be embodied in a program or software. The instructions may be stored in a memory location, such as the memory 1602. The instructions can be directed to the processing unit, which can subsequently program or otherwise configure the processing unit to implement methods of the present disclosure. Examples of operations performed by the processing unit can include fetch, decode, execute, and write back. The processing unit may interpret and/or execute instructions. The processor may include a microprocessor, a data processor, a central processing unit (CPU), a graphical processing unit (GPU), a system-on-chip (SOC), a co-processor, a network processor, an application specific integrated circuit (ASIC), an application specific instruction-set processor (ASIPs), a controller, a programmable logic device (PLD), a chipset, a field programmable gate array (FPGA), or any combination thereof. The processing unit can be part of a circuit, such as an integrated circuit. One or more other components of the system 1600 can be included in the circuit.

The storage unit can store files, such as drivers, libraries and saved programs. The storage unit can store user data (e.g., user preferences and user programs). In some cases, the computer system can include one or more additional data storage units that are external to the computer system, such as located on a remote server that is in communication with the computer system through an intranet or the Internet.

The computer system can communicate with one or more remote computer systems through a network. For instance, the computer system can communicate with a remote computer system of a user (e.g., operator). Examples of remote computer systems include personal computers (e.g., portable PC), slate or tablet PC's (e.g., Apple® iPad, Samsung® Galaxy Tab), telephones, Smart phones (e.g., Apple® iPhone, Android-enabled device, Blackberry®), or personal digital assistants. A user (e.g., client) can access the computer system via the network.

Methods as described herein can be implemented by way of machine (e.g., computer processor) executable code stored on an electronic storage location of the computer system, such as, for example, on the memory 1602 or electronic storage unit 1604. The machine executable or machine-readable code can be provided in the form of software. During use, the processor 1606 can execute the code. In some cases, the code can be retrieved from the storage unit and stored on the memory for ready access by the processor. In some situations, the electronic storage unit can be precluded, and machine-executable instructions are stored on memory.

The code can be pre-compiled and configured for use with a machine have a processer adapted to execute the code or can be compiled during runtime. The code can be supplied in a programming language that can be selected to enable the code to execute in a pre-compiled or as-compiled fashion.

In some embodiments, the processor comprises a code. The code can be program instructions. The program instructions may cause the at least one processor (e.g., computer) to direct a feed forward and/or feedback control loop. In some embodiments, the program instructions cause the at least one processor to direct a closed loop and/or open loop control scheme. The control may be based at least in part on one or more sensor readings (e.g., sensor data). One controller may direct a plurality of operations. At least two operations may be directed by different controllers. In some embodiments, a different controller may direct at least two of operations (a), (b) and (c). In some embodiments, different controllers may direct at least two of operations (a), (b) and (c). In some embodiments, a non-transitory computer-readable medium cause each a different computer to direct at least two of operations (a), (b) and (c). In some embodiments, different non-transitory computer-readable mediums cause each a different computer to direct at least two of operations (a), (b) and (c). The controller and/or computer readable media may direct any of the apparatuses or components thereof disclosed herein. The controller and/or computer readable media may direct any operations of the methods disclosed herein.

In some embodiments, the at least one sensor is operatively coupled to a control system (e.g., computer control system). The sensor may comprise light sensor, acoustic sensor, vibration sensor, chemical sensor, electrical sensor, magnetic sensor, fluidity sensor, movement sensor, speed sensor, position sensor, pressure sensor, force sensor, density sensor, distance sensor, or proximity sensor. The sensor may include temperature sensor, weight sensor, material (e.g., powder) level sensor, metrology sensor, gas sensor, or humidity sensor. The metrology sensor may comprise measurement sensor (e.g., height, length, width, angle, and/or volume). The metrology sensor may comprise a magnetic, acceleration, orientation, or optical sensor. The sensor may transmit and/or receive sound (e.g., echo), magnetic, electronic, or electromagnetic signal. The electromagnetic signal may comprise a visible, infrared, ultraviolet, ultrasound, radio wave, or microwave signal. The gas sensor may sense any of the gas delineated herein. The distance sensor can be a type of metrology sensor. The distance sensor may comprise an optical sensor, or capacitance sensor. The temperature sensor can comprise Bolometer, Bimetallic strip, calorimeter, Exhaust gas temperature gauge, Flame detection, Gardon gauge, Golay cell, Heat flux sensor, Infrared thermometer, Microbolometer, Microwave radiometer, Net radiometer, Quartz thermometer, Resistance temperature detector, Resistance thermometer, Silicon band gap temperature sensor, Special sensor microwave/imager, Temperature gauge, Thermistor, Thermocouple, Thermometer (e.g., resistance thermometer), or Pyrometer. The temperature sensor may comprise an optical sensor. The temperature sensor may comprise image processing. The temperature sensor may comprise a camera (e.g., IR camera, CCD camera). The pressure sensor may comprise Barograph, Barometer, Boost gauge, Bourdon gauge, Hot filament ionization gauge, Ionization gauge, McLeod gauge, Oscillating U-tube, Permanent Downhole Gauge, Piezometer, Pirani gauge, Pressure sensor, Pressure gauge, Tactile sensor, or Time pressure gauge. The position sensor may comprise Auxanometer, Capacitive displacement sensor, Capacitive sensing, Free fall sensor, Gravimeter, Gyroscopic sensor, Impact sensor, Inclinometer, Integrated circuit piezoelectric sensor, Laser rangefinder, Laser surface velocimeter, LIDAR, Linear encoder, Linear variable differential transformer (LVDT), Liquid capacitive inclinometers, Odometer, Photoelectric sensor, Piezoelectric accelerometer, Rate sensor, Rotary encoder, Rotary variable differential transformer, Selsyn, Shock detector, Shock data logger, Tilt sensor, Tachometer, Ultrasonic thickness gauge, Variable reluctance sensor, or Velocity receiver. The optical sensor may comprise a Charge-coupled device, Colorimeter, Contact image sensor, Electro-optical sensor, Infra-red sensor, Kinetic inductance detector, light emitting diode (e.g., light sensor), Light-addressable potentiometric sensor, Nichols radiometer, Fiber optic sensor, Optical position sensor, Photo detector, Photodiode, Photomultiplier tubes, Phototransistor, Photoelectric sensor, Photoionization detector, Photomultiplier, Photo resistor, Photo switch, Phototube, Scintillometer, Shack-Hartmann, Single-photon avalanche diode, Superconducting nanowire single-photon detector, Transition edge sensor, Visible light photon counter, or Wave front sensor. The one or more sensors may be connected to a control system (e.g., to a processor, to a computer).

In various embodiments, a network infrastructure supports a control system for one or more windows such as tintable (e.g., electrochromic) windows. The control system may comprise one or more controllers operatively coupled (e.g., directly or indirectly) to one or more windows. While the disclosed embodiments describe tintable windows (also referred to herein as “optically switchable windows,” or “smart windows”) such as electrochromic windows, the concepts disclosed herein may apply to other types of switchable optical devices comprising a liquid crystal device, an electrochromic device, suspended particle device (SPD), NanoChromics display (NCD), Organic electroluminescent display (OELD), suspended particle device (SPD), NanoChromics display (NCD), or an Organic electroluminescent display (OELD). The display element may be attached to a part of a transparent body (such as the windows).

The tintable window may be disposed in a (non-transitory) facility such as a building, and/or in a transitory facility (e.g., vehicle) such as a car, RV, buss, train, airplane, helicopter, ship, or boat.

In some embodiments, a tintable window exhibits a (e.g., controllable and/or reversible) change in at least one optical property of the window, e.g., when a stimulus is applied. The change may be a continuous change. A change may be to discrete tint levels (e.g., to at least about 2, 4, 8, 16, or 32 tint levels). The optical property may comprise hue, or transmissivity. The hue may comprise color. The transmissivity may be of one or more wavelengths. The wavelengths may comprise ultraviolet, visible, or infrared wavelengths. The stimulus can include an optical, electrical and/or magnetic stimulus. For example, the stimulus can include an applied voltage and/or current. One or more tintable windows can be used to control lighting and/or glare conditions, e.g., by regulating the transmission of solar energy propagating through them. One or more tintable windows can be used to control a temperature within a building, e.g., by regulating the transmission of solar energy propagating through the window. Control of the solar energy may control heat load imposed on the interior of the facility (e.g., building). The control may be manual and/or automatic. The control may be used for maintaining one or more requested (e.g., environmental) conditions, e.g., occupant comfort. The control may include reducing energy consumption of a heating, ventilation, air conditioning and/or lighting systems. At least two of heating, ventilation, and air conditioning may be induced by separate systems. At least two of heating, ventilation, and air conditioning may be induced by one system. The heating, ventilation, and air conditioning may be induced by a single system (abbreviated herein as “HVAC). In some cases, tintable windows may be responsive to (e.g., and communicatively coupled to) one or more environmental sensors and/or user control. Tintable windows may comprise (e.g., may be) electrochromic windows. The windows may be located in the range from the interior to the exterior of a structure (e.g., facility, e.g., building). However, this need not be the case. Tintable windows may operate using liquid crystal devices, suspended particle devices, microelectromechanical systems (MEMS) devices (such as microshutters), or any technology known now, or later developed, that is configured to control light transmission through a window. Windows (e.g., with MEMS devices for tinting) are described in U.S. Pat. No. 10,359,681, issued Jul. 23, 2019, filed May 15, 2015, titled “MULTI-PANE WINDOWS INCLUDING ELECTROCHROMIC DEVICES AND ELECTROMECHANICAL SYSTEMS DEVICES,” and incorporated herein by reference in its entirety. In some cases, one or more tintable windows can be located within the interior of a building, e.g., between a conference room and a hallway. In some cases, one or more tintable windows can be used in automobiles, trains, aircraft, and other vehicles, e.g., in lieu of a passive and/or non-tinting window.

In some embodiments, the tintable window comprises an electrochromic device (referred to herein as an “EC device” (abbreviated herein as ECD), or “EC”). An EC device may comprise at least one coating that includes at least one layer. The at least one layer can comprise an electrochromic material. In some embodiments, the electrochromic material exhibits a change from one optical state to another, e.g., when an electric potential is applied across the EC device. The transition of the electrochromic layer from one optical state to another optical state can be caused, e.g., by reversible, semi-reversible, or irreversible ion insertion into the electrochromic material (e.g., by way of intercalation) and a corresponding injection of charge-balancing electrons. For example, the transition of the electrochromic layer from one optical state to another optical state can be caused, e.g., by a reversible ion insertion into the electrochromic material (e.g., by way of intercalation) and a corresponding injection of charge-balancing electrons. Reversible may be for the expected lifetime of the ECD. Semi-reversible refers to a measurable (e.g., noticeable) degradation in the reversibility of the tint of the window over one or more tinting cycles. In some instances, a fraction of the ions responsible for the optical transition is irreversibly bound up in the electrochromic material (e.g., and thus the induced (altered) tint state of the window is not reversible to its original tinting state). In various EC devices, at least some (e.g., all) of the irreversibly bound ions can be used to compensate for “blind charge” in the material (e.g., ECD).

In some implementations, suitable ions include cations. The cations may include lithium ions (Li+) and/or hydrogen ions (H+) (i.e., protons). In some implementations, other ions can be suitable. Intercalation of the cations may be into an (e.g., metal) oxide. A change in the intercalation state of the ions (e.g., cations) into the oxide may induce a visible change in a tint (e.g., color) of the oxide. For example, the oxide may transition from a colorless to a colored state. For example, intercalation of lithium ions into tungsten oxide (WO3-y (0<y≤˜0.3)) may cause the tungsten oxide to change from a transparent state to a colored (e.g., blue) state. EC device coatings as described herein are located within the viewable portion of the tintable window such that the tinting of the EC device coating can be used to control the optical state of the tintable window.

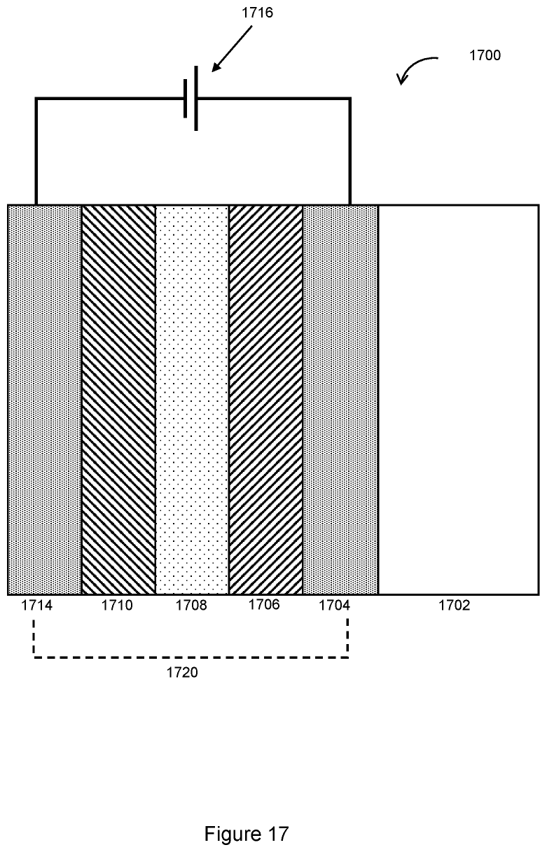

FIG. 17 shows an example of a schematic cross-section of an electrochromic device 1700 in accordance with some embodiments. The EC device coating is attached to a substrate 1702, a transparent conductive layer (TCL) 1704, an electrochromic layer (EC) 1706 (sometimes also referred to as a cathodically coloring layer or a cathodically tinting layer), an ion conducting layer or region (IC) 1708, a counter electrode layer (CE) 1710 (sometimes also referred to as an anodically coloring layer or anodically tinting layer), and a second TCL 1714.

Elements 1704, 1706, 1708, 1710, and 1714 are collectively referred to as an electrochromic stack 1720. A voltage source 1716 operable to apply an electric potential across the electrochromic stack 1720 effects the transition of the electrochromic coating from, e.g., a clear state to a tinted state. In other embodiments, the order of layers is reversed with respect to the substrate. That is, the layers are in the following order: substrate, TCL, counter electrode layer, ion conducting layer, electrochromic material layer, TCL.

In various embodiments, the ion conductor region (e.g., 1708) may form from a portion of the EC layer (e.g., 1706) and/or from a portion of the CE layer (e.g., 1710). In such embodiments, the electrochromic stack (e.g., 1720) may be deposited to include cathodically coloring electrochromic material (the EC layer) in direct physical contact with an anodically coloring counter electrode material (the CE layer). The ion conductor region (sometimes referred to as an interfacial region, or as an ion conducting substantially electronically insulating layer or region) may form where the EC layer and the CE layer meet, for example through heating and/or other processing steps. Examples of electrochromic devices (e.g., including those fabricated without depositing a distinct ion conductor material) can be found in U.S. patent application Ser. No. 13/462,725, filed May 2, 2012, titled “ELECTROCHROMIC DEVICES,” that is incorporated herein by reference in its entirety. In some embodiments, an EC device coating may include one or more additional layers such as one or more passive layers. Passive layers can be used to improve certain optical properties, to provide moisture, and/or to provide scratch resistance. These and/or other passive layers can serve to hermetically seal the EC stack 1720. Various layers, including transparent conducting layers (such as 1704 and 1714), can be treated with anti-reflective and/or protective layers (e.g., oxide and/or nitride layers).

In certain embodiments, the electrochromic device is configured to (e.g., substantially) reversibly cycle between a clear state and a tinted state. Reversible may be within an expected lifetime of the ECD. The expected lifetime can be at least about 5, 10, 15, 25, 50, 75, or 100 years. The expected lifetime can be any value between the aforementioned values (e.g., from about 5 years to about 100 years, from about 5 years to about 50 years, or from about 50 years to about 100 years). A potential can be applied to the electrochromic stack (e.g., 1720) such that available ions in the stack that can cause the electrochromic material (e.g., 1706) to be in the tinted state reside primarily in the counter electrode (e.g., 1710) when the window is in a first tint state (e.g., clear). When the potential applied to the electrochromic stack is reversed, the ions can be transported across the ion conducting layer (e.g., 1708) to the electrochromic material and cause the material to enter the second tint state (e.g., tinted state).

It should be understood that the reference to a transition between a clear state and tinted state is non-limiting and suggests only one example, among many, of an electrochromic transition that may be implemented. Unless otherwise specified herein, whenever reference is made to a clear-tinted transition, the corresponding device or process encompasses other optical state transitions such as non-reflective-reflective, and/or transparent-opaque. In some embodiments, the terms “clear” and “bleached” refer to an optically neutral state, e.g., untinted, transparent and/or translucent. In some embodiments, the “color” or “tint” of an electrochromic transition is not limited to any wavelength or range of wavelengths. The choice of appropriate electrochromic material and counter electrode materials may govern the relevant optical transition (e.g., from tinted to untinted state).

In certain embodiments, at least a portion (e.g., all of) the materials making up electrochromic stack are inorganic, solid (i.e., in the solid state), or both inorganic and solid. Because various organic materials tend to degrade over time, particularly when exposed to heat and UV light as tinted building windows are, inorganic materials offer an advantage of a reliable electrochromic stack that can function for extended periods of time. In some embodiments, materials in the solid state can offer the advantage of being minimally contaminated and minimizing leakage issues, as materials in the liquid state sometimes do. One or more of the layers in the stack may contain some amount of organic material (e.g., that is measurable). The ECD or any portion thereof (e.g., one or more of the layers) may contain little or no measurable organic matter. The ECD or any portion thereof (e.g., one or more of the layers) may contain one or more liquids that may be present in little amounts. Little may be of at most about 100 ppm, 10 ppm, or 1 ppm of the ECD. Solid state material may be deposited (or otherwise formed) using one or more processes employing liquid components, such as certain processes employing sol-gels, physical vapor deposition, and/or chemical vapor deposition.

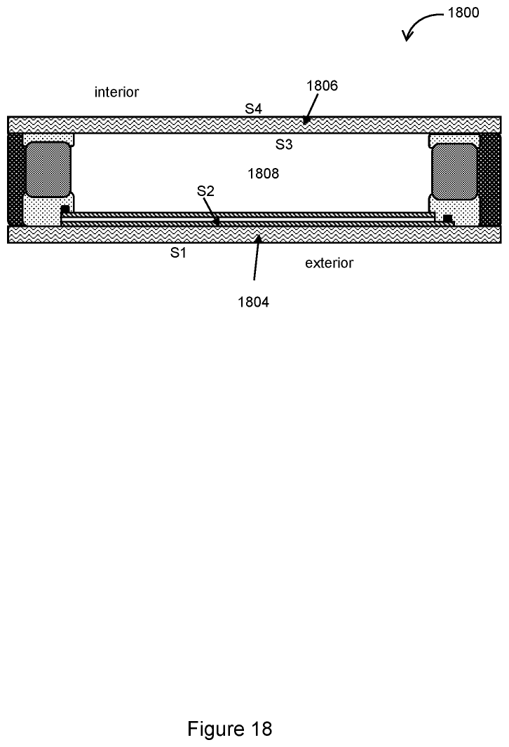

FIG. 18 show an example of a cross-sectional view of a tintable window embodied in an insulated glass unit (“IGU”) 1800, in accordance with some implementations. The terms “IGU,” “tintable window,” and “optically switchable window” can be used interchangeably herein. It can be desirable to have IGUs serve as the fundamental constructs for holding electrochromic panes (also referred to herein as “lites”) when provided for installation in a building. An IGU lite may be a single substrate or a multi-substrate construct. The lite may comprise a laminate, e.g., of two substrates. IGUs (e.g., having double- or triple-pane configurations) can provide a number of advantages over single pane configurations. For example, multi-pane configurations can provide enhanced thermal insulation, noise insulation, environmental protection and/or durability, when compared with single-pane configurations. A multi-pane configuration can provide increased protection for an ECD. For example, the electrochromic films (e.g., as well as associated layers and conductive interconnects) can be formed on an interior surface of the multi-pane IGU and be protected by an inert gas fill in the interior volume (e.g., 1808) of the IGU. The inert gas fill may provide at least some (heat) insulating function for an IGU. Electrochromic IGUs may have heat blocking capability, e.g., by virtue of a tintable coating that absorbs (and/or reflects) heat and light.

In some embodiments, an “IGU” includes two (or more) substantially transparent substrates. For example, the IGU may include two panes of glass. At least one substrate of the IGU can include an electrochromic device disposed thereon. The one or more panes of the IGU may have a separator disposed between them. An IGU can be a hermetically sealed construct, e.g., having an interior region that is isolated from the ambient environment. A “window assembly” may include an IGU. A “window assembly” may include a (e.g., standalone) laminate. A “window assembly” may include one or more electrical leads, e.g., for connecting the IGUs and/or laminates. The electrical leads may operatively couple (e.g., connect) one or more electrochromic devices to a voltage source, switches and the like, and may include a frame that supports the IGU or laminate. A window assembly may include a window controller, and/or components of a window controller (e.g., a dock).

FIG. 18 shows an example implementation of an IGU 1800 that includes a first pane 1804 having a first surface S1 and a second surface S2. In some implementations, the first surface S1 of the first pane 1804 faces an exterior environment, such as an outdoors or outside environment. The IGU 1800 also includes a second pane 1806 having a first surface S3 and a second surface S4. In some implementations, the second surface (e.g., S4) of the second pane (e.g., 1806) faces an interior environment, such as an inside environment of a home, building, vehicle, or compartment thereof (e.g., an enclosure therein such as a room).

In some implementations, the first and the second panes (e.g., 1804 and 1806) are transparent or translucent, e.g., at least to light in the visible spectrum. For example, each of the panes (e.g., 1804 and 1806) can be formed of a glass material. The glass material may include architectural glass, and/or shatter-resistant glass. The glass may comprise a silicon oxide (SOₓ). The glass may comprise a soda-lime glass or float glass. The glass may comprise at least about 75% silica (SiO₂). The glass may comprise oxides such as Na₂O, or CaO. The glass may comprise alkali or alkali-earth oxides. The glass may comprise one or more additives. The first and/or the second panes can include any material having suitable optical, electrical, thermal, and/or mechanical properties. Other materials (e.g., substrates) that can be included in the first and/or the second panes are plastic, semi-plastic and/or thermoplastic materials, for example, poly(methyl methacrylate), polystyrene, polycarbonate, allyl diglycol carbonate, SAN (styrene acrylonitrile copolymer), poly(4-methyl-1-pentene), polyester, and/or polyamide. The first and/or second pane may include mirror material (e.g., silver). In some implementations, the first and/or the second panes can be strengthened. The strengthening may include tempering, heating, and/or chemically strengthening.

While preferred embodiments of the present invention have been shown, and described herein, it will be obvious to those skilled in the art that such embodiments are provided by way of example only. It is not intended that the invention be limited by the specific examples provided within the specification. While the invention has been described with reference to the afore-mentioned specification, the descriptions and illustrations of the embodiments herein are not meant to be construed in a limiting sense. Numerous variations, changes, and substitutions will now occur to those skilled in the art without departing from the invention. Furthermore, it shall be understood that all aspects of the invention are not limited to the specific depictions, configurations, or relative proportions set forth herein which depend upon a variety of conditions and variables. It should be understood that various alternatives to the embodiments of the invention described herein might be employed in practicing the invention. It is therefore contemplated that the invention shall also cover any such alternatives, modifications, variations, or equivalents. It is intended that the following claims define the scope of the invention and that methods and structures within the scope of these claims and their equivalents be covered thereby.

What is claimed is:

1. A method of engaging at least one target personnel in a facility with a targeted stimulus, the method comprising:
providing device data to a device database that associates an interactive device disposed in the facility with an interaction zone and with a stimulus type of the interactive device, the interactive device being configured to provide the stimulus type to the interaction zone;
identifying a stimulus context pertinent to at least one target personnel that is presently at the interaction zone and/or that is projected to be in the interaction zone at a projected future time;
obtaining contextual data relating to the stimulus context, the contextual data being obtained from a contextual database; and
using the stimulus type of the interactive device to disseminate the contextual data to the interaction zone.

2-3. (canceled)

4. The method of claim 1, wherein the stimulus type comprises visual, auditory, olfactory, tactile, gustatory, electrical, or magnetic stimulus or a combination thereof.

5. The method of claim 1, wherein the stimulus type comprises temperature, gas content of the atmosphere at least in in the interaction zone of the facility, gas flow, gas pressure, electromagnetic radiation, sound, or gas content of the atmosphere, or a combination thereof.

6-19. (canceled)

20. The method of claim 1, wherein the stimulus type comprises is accessible and/or perceptible by one or more occupants of the interaction zone.

21. The method of claim 20, wherein the one or more occupants comprise the target personnel.

22. The method of claim 1, wherein the device data includes a designation of the interaction zone.

23. The method of claim 22, wherein the designation comprises determining and/or using an isovist corresponding to the stimulus type of the interactive device.

24-25. (canceled)

26. The method of claim 22, wherein designation of the interaction zone comprises an identifier of the interactive device, a geographic location of the interactive device, an orientation of the interactive device, or a boundary description of a zone in which the stimulus type is perceptible to the target personnel.

27. The method of claim 1, wherein the contextual data is disseminated using the stimulus type from the interactive device, and the stimulus type is recognizable by the at least one target personnel in the interaction zone.

28. The method of claim 1, wherein (i) identification of the stimulus context, (ii) obtaining the contextual data, or (iii) identification of the stimulus context and obtaining of the contextual data, is provided by: one or more of a third party, a media outlet, a commercial outlet, a security outlet, a health outlet, an owner, lessor, manager, or messenger of the facility, or a combination thereof.

29-36. (canceled)

37. The method of claim 1, wherein a location of the target personnel at a projected future time is determined based at least in part on a path projection, on an electronically stored schedule and/or calendar of one or more activities taking place in the facility, on an electronically stored schedule and/or calendar of the target personnel, or a combination thereof.

38-39. (canceled)

40. The method of claim 1, wherein a location of the target personnel is determined using geolocation data.

41. (canceled)

42. The method of claim 1, wherein the interactive device disseminates the contextual data as one or more of displayed and/or projected media, projected sound, a projected temperature wherein the stimulus type is thermal, a projected gas, or a combination thereof.

43-44. (canceled)

45. The method of claim 42, wherein:
the projected media comprises a message; and
the message comprises a commercial message, a health related message, a security related message, an informative message regarding the facility, or an informative message regarding activities in the facility.

46. The method of claim 1, wherein the facility comprises an airport, a bank, a hospital, a sport arena, a hotel, a club, a restaurant, a country club, a resort, a mall, a shop, a theater, a transportation terminal, a school, a museum, an office, a gym, a warehouse, a distribution center, or a factory.

47-67. (canceled)

68. The method of claim 1, wherein the method is carried out at least in part by a local network that comprises cables configured to transmit communication data and power on one cable.

69. (canceled)

70. The method of claim 68, wherein the communication data comprises control data configured to control (i) one or more devices of the facility other than the interactive device and/or (ii) an environment of at least a portion of the facility other than the interaction zone.

71. The method of claim 68, wherein the communication data comprises cellular communication conforming to at least third, fourth, or fifth generation cellular communication, phone communication, media streaming that comprises television, movie, stills, gaming, video conferencing, data sheets, media utilized by an industry sector or by a governmental sector, media utilized in entertainment, health, construction, aviation, security, technology, biotechnology, legal, banking, monetary, automotive, agricultural, communication, education, food, computer, military, oil and gas, sports, manufacturing, or in waste management industry, or a combination thereof.

72-76. (canceled)

77. The method of claim 1, wherein the stimulus type is a first stimulus type, wherein the method further comprises engaging the at least one target personnel in the interaction zone of the facility with at least one stimulus type different than the first stimulus type.

78-89. (canceled)

90. A method for managing delivery of targeted stimulus from contextual data sources to one or more interactive devices in a facility, comprising:
deploying an interactive device in the facility, the interactive device being configured to provide a stimulus type to at least one target personnel;
mapping an interaction zone in the facility where the stimulus type is perceptible by the target personnel;
discovering device data that enables remote engagement with at least one interaction capability of the interactive device;
publishing the device data and a representation of the interaction zone in a database available to a content manager; and
using the database and a stimulus context pertinent to the at least one target personnel that is presently at and/or that is projected to be in the interaction zone at a future time, to disseminate contextual data to the interaction zone using the interactive device, the contextual data being contextual data obtained from a contextual database.

91-255. (canceled)
